(19) United States
(12) Patent Application Publication
(10) Pub. No.: US 2024/0178352 A1
(43) Pub. Date: May 30, 2024

(54) LIGHT EMITTING DEVICE

(71) Applicant: NICHIA CORPORATION, Anan-shi (JP)

(72) Inventor: Soichiro MIURA, Tokushima-shi (JP)

(21) Appl. No.: 18/519,900

(22) Filed: Nov. 27, 2023

(30) Foreign Application Priority Data
Nov. 30, 2022 (JP) 2022-191433

(51) Int. Cl. H01L 33/50; H01L 33/48; H01L 33/58

(52) U.S. Cl. CPC H01L 33/507; H01L 33/483; H01L 33/502; H01L 33/58

(57) ABSTRACT

A light emitting device includes a base, a light emitting element, a wavelength conversion member, a lens member, and a frame part. The light emitting element is disposed on an upper surface of the base and configured to emit light. The wavelength conversion member is disposed on the upper surface of the base. The wavelength conversion member has an incident surface on which the light is to be incident, and a light emission surface through which the light is extracted out of the wavelength conversion member. The light emission surface is different from the incident surface. The lens member is bonded to the wavelength conversion member on a light emission surface side of the wavelength conversion member. The frame part is connected to the base and forms a sealed space in which the light emitting element, the wavelength conversion member, and the lens member are sealed.

### CROSS REFERENCE TO RELATED APPLICATION

This application claims priority to Japanese Patent Applications No. 2022-191433, filed on Nov. 30, 2022, the entire content of which is hereby incorporated herein by reference.

### BACKGROUND

The present disclosure relates to a light emitting device.

In a light emitting device that converts the wavelength of laser light, the wavelength converted light might be controlled by using a collimating lens or the like. Japanese Patent Publication No. 2013-254690 discloses a light emitting device having a semiconductor laser and configured such that laser light emitted from the semiconductor laser is incident on a ceramic phosphor part and is converted to a different wavelength conversion so as to emit illumination light to the outside of the housing. In the light emitting device disclosed in Japanese Patent Publication No. 2013-254690, a lens is provided on the outside of the housing to control the illumination light.

### SUMMARY

The technology disclosed in the patent publication described above uses a lens disposed on the outside of the housing to control the wavelength converted light which makes the housing structure complex. There is room for improvement in achieving a light emitting device having a lens by employing a more simplified structure.

A light emitting device according to one embodiment of the present disclosure includes a base, a light emitting element, a wavelength conversion member, a lens member, and a frame part. The light emitting element is disposed on an upper surface of the base and configured to emit light. The wavelength conversion member is disposed on the upper surface of the base. The wavelength conversion member has an incident surface on which the light is to be incident, and a light emission surface through which the light is extracted out of the wavelength conversion member. The light emission surface is different from the incident surface. The lens member is bonded to the wavelength conversion member on a light emission surface side of the wavelength conversion member. The frame part is connected to the base and forms a sealed space in which the light emitting element, the wavelength conversion member, and the lens member are sealed.

According to an embodiment of the present disclosure, a light emitting device including a lens and having a simple package structure can be achieved.

### BRIEF DESCRIPTION OF THE DRAWINGS

FIG. 1 is a schematic perspective view illustrating a light emitting device according to a first embodiment and a second embodiment.

FIG. 2 is a schematic perspective view of the light emitting device in FIG. 1 when the cover is removed.

FIG. 3 is a schematic top view of the device in FIG. 2.

FIG. 4 is a schematic cross-sectional view of the light emitting device according to the first embodiment taken along line IV-IV in FIG. 1.

FIG. 5 is a schematic perspective view of a wavelength conversion member according to the embodiment.

FIG. 6 is a schematic cross-sectional view of the wavelength conversion member taken along line VI-VI in FIG. 5.

FIG. 7 is a schematic perspective view of a phosphor part according to the embodiment.

FIG. 8 is a schematic enlarged top view enlarging the portion X in the top view of the light emitting device shown in FIG. 3.

FIG. 9 is a schematic enlarged cross-sectional view enlarging the portion Y in the cross-sectional view of the light emitting device shown in FIG. 4.

FIG. 10 is a schematic enlarged view of the portion Y in the corresponding cross-sectional view of a variation of the light emitting device of the first embodiment.

FIG. 11 is a schematic cross-sectional view of a light emitting device according to the second embodiment taken along line XI-XI in FIG. 1.

FIG. 12 is a schematic enlarged cross-sectional view enlarging the portion Z in the cross-sectional view of the light emitting device shown in FIG. 11.

FIG. 13 is a schematic perspective view illustrating a light emitting device according to a third embodiment.

FIG. 14 is a schematic top view of the light emitting device shown in FIG. 13.

FIG. 15 is a schematic cross-sectional view of the light emitting device taken along line XV-XV in FIG. 14.

FIG. 16 is a schematic perspective view of a variation of the light emitting device according to the third embodiment.

FIG. 17 is a schematic top view of the light emitting device shown in FIG. 16.

FIG. 18 is a schematic cross-sectional view of the light emitting device taken along line XVIII-XVIII in FIG. 17.

FIG. 19 is a schematic perspective view illustrating a light emitting device according to a fourth embodiment.

FIG. 20 is a schematic perspective view of the light emitting device shown in FIG. 19 when the cover is removed.

FIG. 21 is a schematic top view corresponding to FIG. 20.

FIG. 22 is a schematic cross-sectional view of the light emitting device taken along line XXII-XXII in FIG. 19.

FIG. 23 is a schematic cross-sectional view of the light emitting device taken along line XXIII-XXIII in FIG. 19.

FIG. 24 is a schematic enlarged cross-sectional view enlarging the portion A in FIG. 23.

### DETAILED DESCRIPTION

Certain forms for implementing the present invention will be explained below with reference to the accompanying drawings. Terms indicating specific directions or positions (e.g., “upper,” “lower,” and other terms including these) might be used as needed. These terms indicating specific directions or positions such as “upper” or “lower” used in the present specification, however, are merely used in order to clearly show the relative directions or positions of the constituents or members, and do not have to match the relationships of the members in use, for example. The same reference numerals denote the same or similar portions or members appearing in multiple drawings.

In the present disclosure, a polygon, such as a triangle, rectangle, or the like, includes a polygonal shape with modified corners such as a rounded corner, a slanted corner, an inverted-round corner, or the like. Moreover, the location of such modification is not limited to a corner (an end of a side).

A shape with modification in the intermediate portion of a side will similarly be referred to as a polygon. In other words, any polygon-based shape with modification should be understood to be included in the interpretation of a “polygon” described in the present disclosure.

This similarly applies to any word describing a specific shape, such as a trapezoidal, circular, recessed, or projected shape, without being limited to a polygon. This also similarly applies to the sides defining such shapes. In other words, even if a corner or intermediate portion of a side is subjected to processing, the term “side” should be interpreted to include the processed portion. To distinguish a “polygon” or “side” that is intentionally not processed from a shape subjected to processing, the shape will be described by adding the phrase “exact,” such as “an exact rectangle.”

The embodiments described below illustrating light emitting devices and the like are provided to give a concrete form to the technical ideas of the present invention, and are not intended to limit the present invention. The sizes, shapes, and relative positions of, and materials for, the members explained in the description below are not intended to limit the scope of the present invention to only those described unless otherwise noted, and are intended for illustration purposes. Moreover, what is explained in relation to one embodiment is also applicable to other embodiments or their variations. The sizes of and relative positions of the members shown in the drawings might be exaggerated for clarity of explanation. Furthermore, for the purpose of not making the drawings excessively complex, schematic diagrams omitting certain elements might be used, or only a cut-end surface might be shown as a schematic cross-sectional view.

### First Embodiment

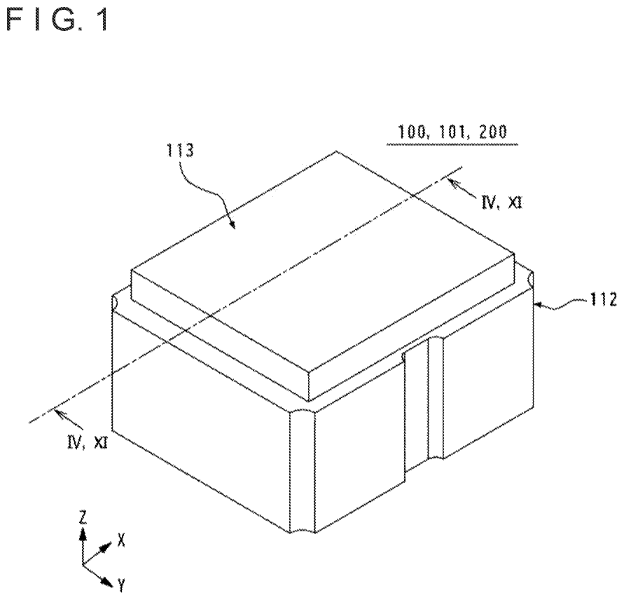

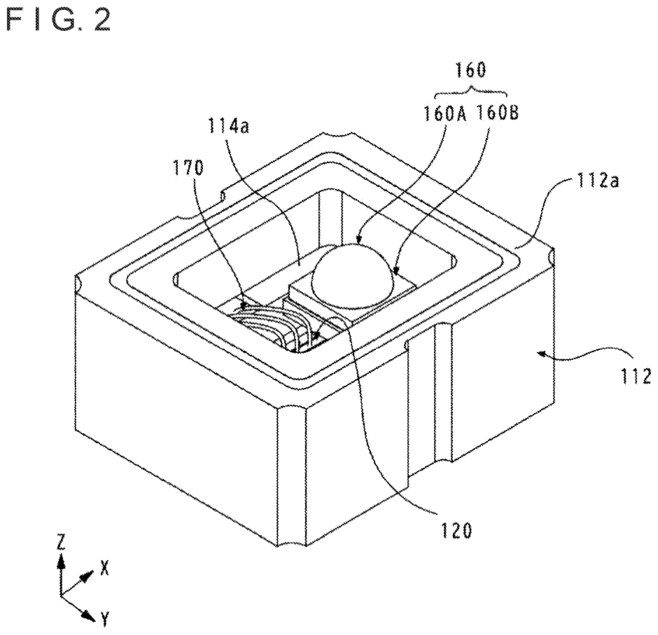

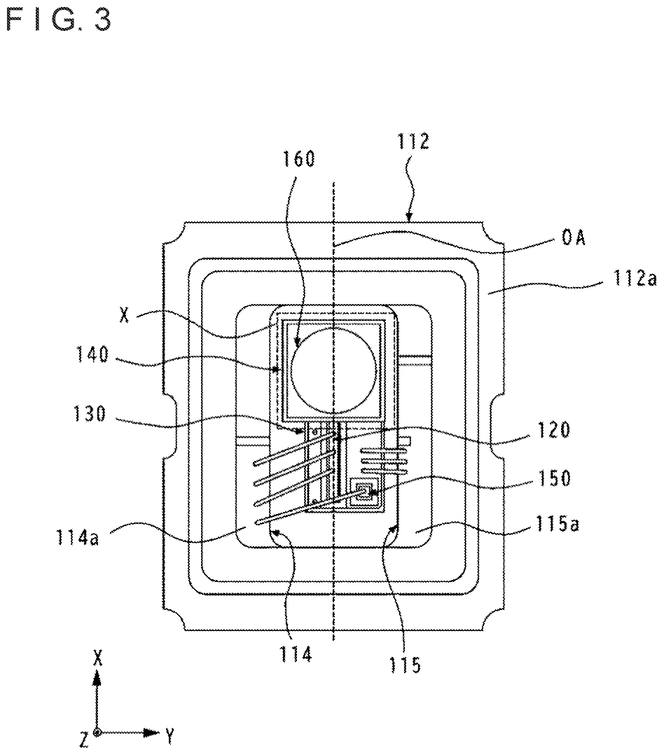

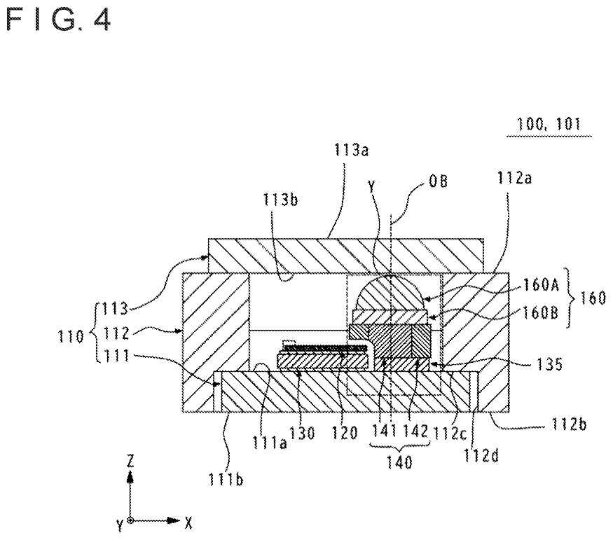

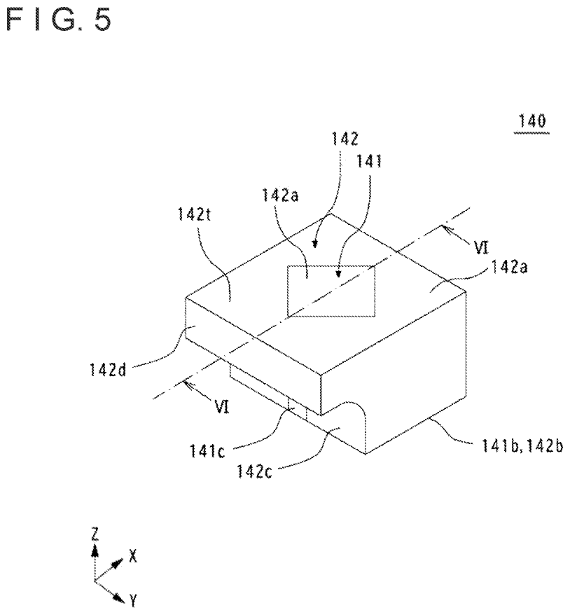

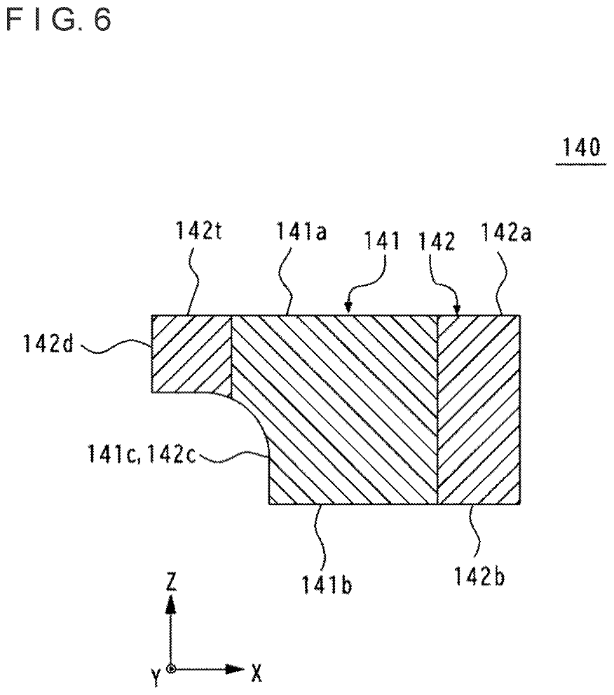

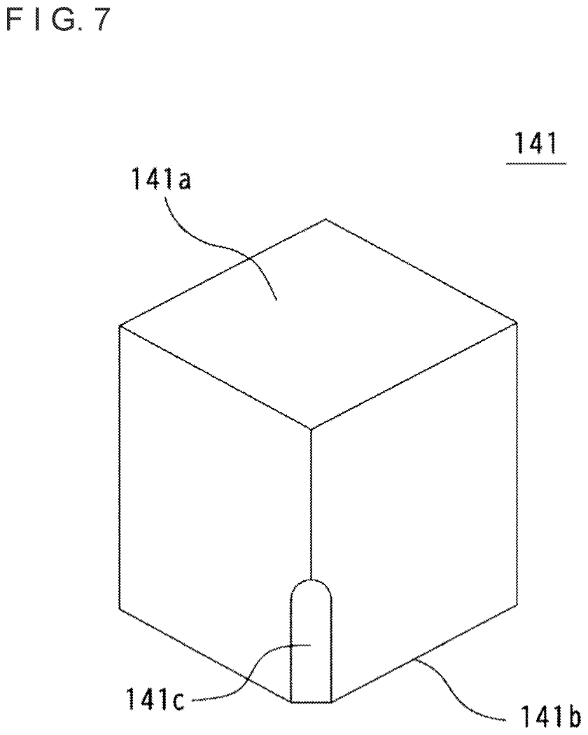

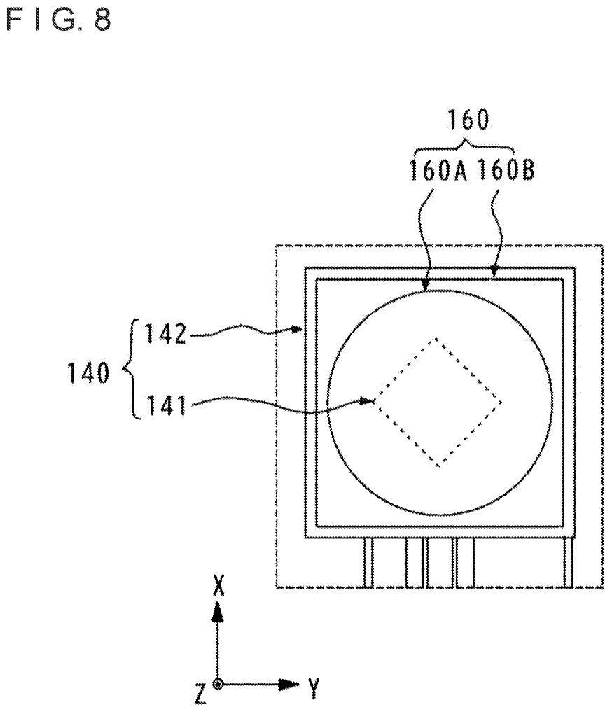

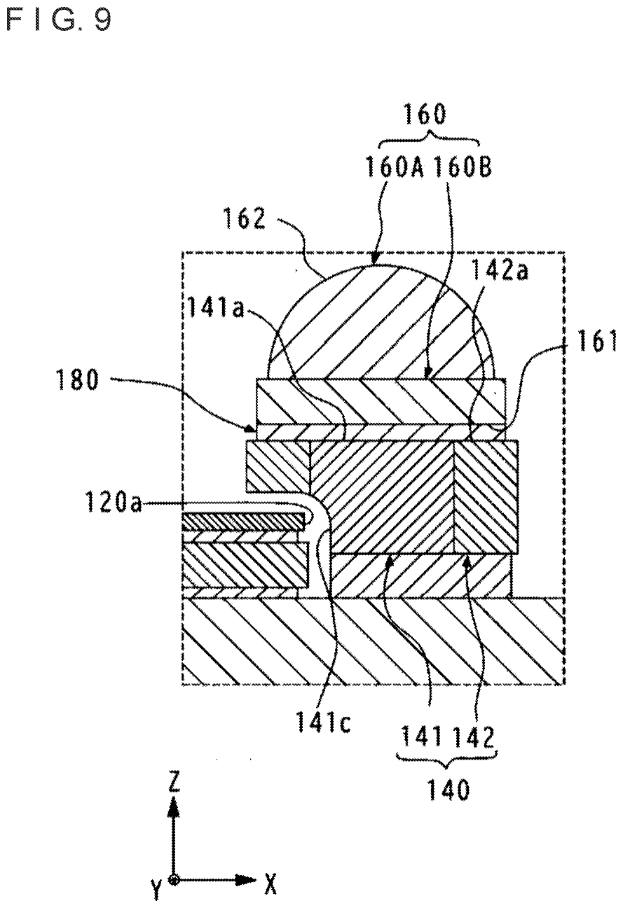

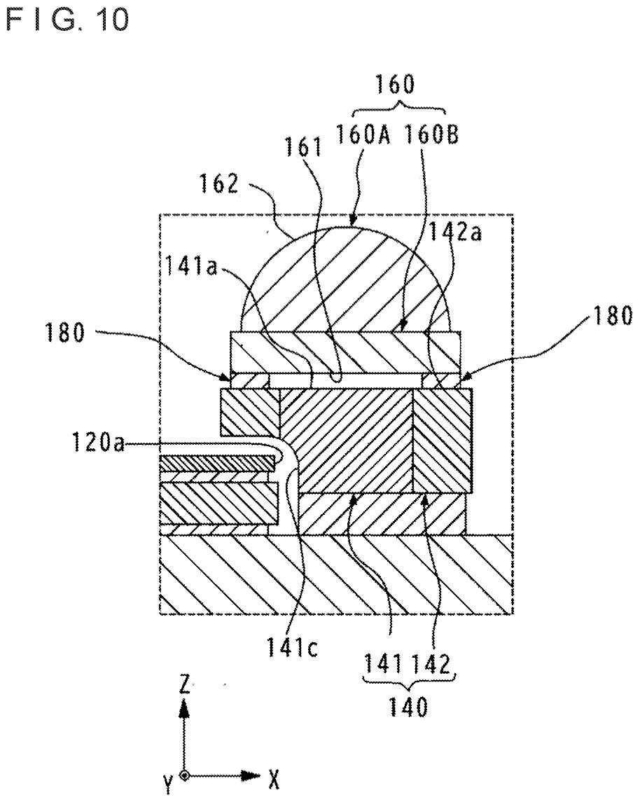

Light emitting devices 100 and 101 according to a first embodiment will be explained with reference to FIG. 1 to FIG. 10. FIG. 1 is a schematic perspective view illustrating the light emitting device 100/101. FIG. 2 is a schematic perspective view of the light emitting device 100/101 shown in FIG. 1 when the cover 113 is removed. FIG. 3 is a schematic top view of the light emitting device 100/101 shown without the cover in FIG. 2. FIG. 4 is a schematic cross-sectional view of the light emitting device 100/101 taken along line IV-IV in FIG. 1. FIG. 5 is a schematic perspective view of a wavelength conversion member 140. FIG. 6 is a schematic cross-sectional view of the wavelength conversion member 140 taken along line VI-VI in FIG. 5. FIG. 7 is a schematic perspective view illustrating a phosphor part 141. FIG. 8 is a schematic enlarged top view enlarging the portion X in the top view of the light emitting device 100/101 shown in FIG. 3. FIG. 9 is a schematic enlarged cross-sectional view enlarging the portion Y in the cross-sectional view of the light emitting device 100 shown in FIG. 4. FIG. 10 is a schematic enlarged cross-sectional view enlarging the portion Y of the light emitting device 101 which is a variation shown in FIG. 4.

A light emitting device 100 includes a package 110, a light emitting element 120, a wavelength conversion member 140, and a lens member 160. In the example illustrated, the light emitting devices further include submounts 130 and 135, a protective device 150, wires 170, and a bonding member 180. These constituent elements are optional.

Each constituent element of the light emitting device 100 will be explained with reference to FIG. 1 to FIG. 10.

In FIG. 1 to FIG. 6 and FIG. 8 to FIG. 10, the X-axis, Y-axis, and Z-axis that are orthogonal to one another are provided for reference purposes. The directions parallel to the X-axis, Y-axis, and Z-axis are designated as the first direction X, the second direction Y, and the third direction Z, respectively.

### Package 110

A package 110 includes a base 111, a lateral part 112, and a cover 113. The base 111 has an upper surface 111a and a lower surface 111b. The outer shape of the base 111 is rectangular when viewed from above. The rectangular shape may have long sides and short sides. The outer shape of the base 111 does not have to be a rectangular shape. Unless specifically stated to exclude a square, the term “rectangular shape” in the present specification may include a square.

The lateral part 112 is connected to the upper surface 111a of the base 111 and extends upwards from the upper surface 111a. The lateral part 112 has an upper surface 112a, a first lower surface 112b, one or more inner lateral surfaces, and one or more outer lateral surfaces. The upper surface 112a of the lateral part 112 meets the one or more outer lateral surfaces. The outer perimeter of the upper surface 112a is, for example, rectangular. The inner perimeter of the upper surface 112a is, for example, rectangular. The one or more inner lateral surfaces of the lateral part 112 meet the upper surface 111a of the base 111.

The base 111 and the lateral part 112 form a recess that is recessed from the upper surface 112a of the lateral part 112 towards the upper surface 111a of the base 111. The recess is formed inward of the outline of the lateral part 112 when viewed from above. At least a portion of the upper surface 111a of the base 111 is surrounded by a frame formed by the one or more inner lateral surfaces of the lateral part 112 when viewed from above. The outline of this frame is a rectangle having long and short sides. The base 111 and the lateral part 112 are separately formed and then bonded together. The base 111 and the lateral part 112 may be integrally formed.

In the package 110, the lateral part 112A includes a stepped portion projecting inward. Specifically, the lateral part 112 has a first stepped part 114 or/and a second stepped part 115 when viewed from above. In the example shown in FIGS. 2 and 3, the lateral part 112 has an upper surface 114a and an upper surface 115a along the two sides of the inner perimeter of the upper surface 112a that extends in the first direction X when viewed from above. When viewed from above, the upper surface 114a is provided along one of the sides of the upper surface 112a that extend in the first direction X. When viewed from above the upper surface 115a is provided along the other side of the sides of the upper surface 112a that extend in the first direction X. In the lateral part 112, the upper surface 114a and the upper surface 115a are provided across the entire lengths of the sides that extend in the first direction X. The first stepped part 114 has an inner lateral surface meeting the upper surface 114a and extending downwards. The second stepped part 115 has an inner lateral surface meeting the upper surface 115a and extending downwards.

The upper surface 114a and the upper surface 115a are positioned higher than the upper surface 111a of the base 111 and lower than the upper surface 112a of the lateral part 112. Furthermore, the upper surface 114a and the upper surface 115a can parallel the upper surface 111a of the base 111.

The first stepped part 114 and the second stepped part 115 will be explained now. The first stepped part 114 refers to a portion composed of the upper surface 114a and the inner lateral surface meeting the upper surface 114a and extending downwards. Similarly, the second stepped part 115 refers to the portion composed of the upper surface 115a and the inner lateral surface meeting the upper surface 115a and extending downwards. The inner lateral surface extending downwards from the upper surface 112a of the lateral part 112 and meeting the upper surface 114a is not included in the first stepped part 114. Similarly, the inner lateral surface extending downwards from the upper surface 112a of the lateral part 112 and meeting the upper surface 115a is not included in the second stepped part 115.

A single-layer or multilayered metal film may be disposed on the upper surface 114a and the upper surface 115a. Furthermore, a single-layer or multilayered metal film may be disposed on the first lower surface 112b. The metal films disposed on the lower surface 112b, the upper surface 114a, and the upper surface 115a are electrically connected by the vias/wiring provided in the interior of the lateral part 112. A single-layer or multilayered metal film may be disposed on the upper surface 112a to be electrically connected to the single-layer or multilayered metal film disposed on the upper surface 114a or/and the upper surface 115a. For such a metal film, for example, Ni/Au (a metal film layered in the order of Ni and Au), Ti/Pt/Au (a metal film layered in the order of Ti, Pt, and Au), or the like can be used.

As shown in FIG. 4, the lateral part 112 may further have a second lower surface 112c that is in contact with the upper surface 111a of the base 111. The second lower surface 112c is bonded to the upper surface 111a of the base 111 via, for example, a metal adhesive. In the example illustrated, when viewed from above, the second lower surface 112c overlaps a portion of the upper surface 112a. The lateral part 112 can further have one or more lateral surfaces 112d that meet the second lower surface 112c and extend downwards. These lateral surfaces 112d further meet the first lower surface 112b. The second lower surface 112c, for example, parallels the upper surface 111a of the base 111. In the example illustrated, the lateral surfaces 112d are spaced apart from the lateral surfaces of the base 111.

As shown in FIG. 1 and FIG. 4, the cover 113 has an upper surface 113a, a lower surface 113b, and one or more lateral surfaces that meet the upper surface 113a and the lower surface 113b. The one or more lateral surfaces connect the outer perimeter of the upper surface 113a and the outer perimeter of the lower surface 113b. The cover 113 has, for example, a rectangular-parallelepiped or cubic shape. In this case, the upper surface 113a and the lower surface 113b of the cover 113 are both rectangular, and the cover 113 has four rectangular lateral surfaces. The cover 113, however, is not limited to have a rectangular-parallelepiped or cubic shape. In other words, the shape of the cover 113 when viewed from above is not limited to a rectangle, and can be any shape, such as a circle, ellipse, or polygon.

The cover 113 is supported by the lateral part 112, and is positioned above the upper surface 111a of the base 111. The peripheral portion of the lower surface 113b of the cover 113 is bonded to the upper surface 112a of the lateral part 112, for example. Bonding the cover 113 to the lateral part 112 creates a sealed space that is surrounded by the base 111, the lateral part 112, and the cover 113. The lower surface 113b faces the upper surface 111a of the base 111 via the sealed space. At least a portion of the lower surface 113b defines the sealed space. As described later, in the present specification, the lateral part 112 and the cover 113 may be collectively referred to as the “frame part” on occasion.

In the direction perpendicular to the upper surface 111a of the base 111 (the third direction Z), the distance from the upper surface 111a of the base 111 to the upper surface 114a of the first stepped part 114 (or the upper surface 115a of the second stepped part 115) is smaller than the distance from the upper surface 114a of the first stepped part 114 (or the upper surface 115a of the second stepped part 115) to the lower surface 113b of the cover 113. In other words, the upper surface 114a (or the upper surface 115a) is positioned lower than one half the height of the sealed space that is created by the base 111, the lateral part 112, and the cover 113.

The base 111 can be formed by using, for example, a metal as a main material. For the metal, for example, copper, copper alloy, or the like can be used. The lateral part 112 can be formed by using, for example, a ceramic as a main material. For the ceramic material, for example, aluminum nitride, silicon nitride, aluminum oxide, or silicon carbide can be used. The base 111 and the lateral part 112 can be integrally formed from the same material. For example, these members may be formed with a ceramic as a main material, or another insulating material as a main material.

The cover 113 has a light transmitting region that allows light of a predetermined wavelength to pass therethrough. At least one portion of the lower surface 113b of the cover 113 is an incident surface, and at least one portion of the upper surface 113a is a light emission surface. The light transmitting region of the cover 113 can be formed by using, for example, sapphire as a main material. Sapphire is a material that has relatively high light transmissivity as well as relatively high strength. For the main material for the light transmitting region of the cover 113, for example, a light transmissive material, such as quartz, silicon carbide, or glass may be used besides sapphire. The cover 113 may be entirely formed as a light transmissive region.

### Light Emitting Element 120

In the light emitting device 100 illustrated in the drawings, a single light emitting element 120 is installed. The light emitting device 100 may have a plurality of light emitting elements. The light emitting element 120 emits light having directivity. The light emitting element 120 is, for example, a semiconductor laser element. In the light emitting device 100 illustrated in FIG. 1 to FIG. 4, a semiconductor laser element is employed as the light emitting element 120.

The light emitting element 120 has, for example, a rectangular outline when viewed from above. The lateral surface of the light emitting element 120 that meets one of the short sides of the rectangle serves as the light emission surface. The upper surface and the lower surface of the light emitting element 120 have larger areas than the emission surface.

The case in which the light emitting element 120 is a semiconductor laser element will be explained now. The light (laser light) emitted from the light emitting element 120 is divergent and exhibits an elliptical far field pattern (hereinafter referred to as “FFP”) in a plane parallel to the emission surface. The FFP is the shape or the optical intensity distribution of the emitted light at a location away from the emission surface.

Based on the elliptical shape of FFP of light emitted from the light emitting element 120, the direction of the major diameter of the elliptical shape is referred to as the fast axis direction and the direction of the minor diameter is referred to as the slow axis direction. The fast axis direction of an FFP of the light emitting element 120 can coincide with the direction in which the semiconductor layers, including the active layer, of the light emitting element 120 are stacked.

Furthermore, based on the light intensity distribution of an FFP of the light emitting element 120, the portion having the intensity of at least 1/e² of the peak intensity can be referred to as the main portion of the light. Based on light intensity distribution, the angle corresponding to the 1/e² intensity is referred to as the divergence angle. The divergence angle in the fast axis direction of an FFP is larger than the divergence angle in the slow axis direction of the FFP.

The light at the center of the elliptical shape of an FFP, i.e., the light exhibiting the peak intensity in the light intensity distribution of the FFP, is referred to as the light traveling along the optical axis. The optical path of the light traveling along the center of the elliptical shape of an FFP is referred to as the optical axis of the light.

For the light emitting element 120, a light emitting element configured to emit blue, green, or red light can be used. In the present disclosure, blue light emitted by the light emitting element 120 refers to light having a peak emission wavelength in the range of 420 nm to 494 nm. Green light refers to light having a peak emission wavelength in the range of 495 nm to 570 nm. Red light refers to light having a peak emission wavelength in the range of 605 nm to 750 nm. A blue or green light emitting element 120 is, for example, a semiconductor laser diode including a nitride semiconductor. For a nitride semiconductor, for example, GaN, InGaN, or AlGaN can be used. Exampled of a red light emitting element 120 includes a semiconductor laser element including any of InAlGaP based, GaInP based, GaAs based, and AlGaAs based semiconductors.

The color of light emitted from the light emitting element 120 is not limited to these. The light emitting element 120 may emit light having a wavelength out of the wavelength ranges described above.

### Submount 130

A submount 130 has a rectangular-parallelepiped shape, for example, and has a lower surface, an upper surface, and one or more lateral surfaces. The submount 130 has the smallest width in the up/down direction. The shape of the submount 130 is not limited to a rectangular-parallelepiped shape. The submount 130 is formed by using, for example, aluminum nitride or silicon carbide, but other materials can be used. The submount 130 may include a metal part that is 1 μm to 300 μm in thickness, for example, disposed on the upper surface of the submount 130. For the metal part, for example, copper can be used. With the metal part, the heat dissipation performance of the submount can be increased. Furthermore, a metal film can be disposed on the upper surface of the metal part. For the metal film, for example, Ni/Au (metal film layered in the order of Ni and Au), Ti/Pt/Au (metal film made layered in the order of Ti, Pt, Au), or the like can be used. The metal part and the metal film may be omitted as desired.

### Submount 135

A submount 135 is, for example, a rectangular-parallelepiped shape similar to the submount 130, and one made of the same material as that for the submount 130 can be used. One having a different shape and material from those of the submount 130 may be used.

### Wavelength Conversion Member 140

A wavelength conversion member 140 is a member that converts the incident light having a certain wavelength into light of a different wavelength. The wavelength conversion member 140 according to this embodiment has a light incident surface on which light is to be incident and a light emission surface at a location different from the light incident surface.

In the example shown in FIG. 5 and FIG. 6, the wavelength conversion member 140 has a phosphor part 141 and a surrounding part 142. The phosphor part 141 has a light incident surface on which light is to be incident. The surrounding part 142 has inner lateral surfaces that surround the lateral surfaces of the phosphor part 141. Not all surfaces of the phosphor part 141 are surrounded by the surrounding part 142. At least the light incident surface and the light emission surface of the phosphor part 141 are not surrounded by the surrounding part, and thus are exposed. In the example illustrated, the incident lateral surface 141c of the phosphor part 141 constitutes at least a portion of the light incident surface of the wavelength conversion member 140, and the upper surface 141a constitutes at least a portion of the light emission surface of the wavelength conversion member 140. The wavelength conversion member 140 does not have to be made of a phosphor part 141 and a surrounding part 142, and may be made only of a phosphor part 141, for example.

The phosphor part 141 will be explained further with reference to FIG. 7. The phosphor part 141 has a lower surface 141b opposite the upper surface 141a. The phosphor part 141 further has lateral surfaces that include the incident lateral surface 141c. In the example of a phosphor part 141 shown in FIG. 5, the lateral surfaces excluding the incident lateral surface 141c are surrounded by the surrounding part 142.

The surrounding part 142 will be explained next. The surrounding part 142 has an upper surface 142a, one or more lower surfaces opposite the upper surface, inner lateral surfaces meeting the inner perimeter of the upper surface 142a and being in contact with the lateral surfaces of the phosphor part 141, and outer lateral surfaces meeting the outer perimeter of the upper surface 142a or/and the outer perimeter of the lower surface. In the surrounding part 142, the incident light of a certain wavelength is reflected at one or more of the inner lateral surfaces. The reflectance can be, for example, 80% to 100%.

The surrounding part 142 covers the lateral surfaces of the phosphor part 141. Meanwhile, the incident lateral surface 141c of the phosphor part 141 is not covered by the surrounding part 142, but is exposed from the surrounding part 142. With this structure, light having been incident on the incident lateral surface 141c and exited the other lateral surfaces of the phosphor part 141 is reflected back to the phosphor part 141. The light that entered the phosphor part 141 exits through the upper surface 141a.

When viewed from above, all of the sides of the surrounding part 142 that connect the outer lateral surfaces and the upper surface 142a are apart from the lateral surfaces of the phosphor part 141. In the example illustrated, a connection surface 142c, which is one of the outer lateral surfaces of the surrounding part 142, forms a single flat surface or a surface including a curved surface that is continuous with the incident lateral surface 141c of the phosphor part 141. In the example illustrated, the connection surface 142c forms a surface that is continuous with the incident lateral surface 141c, in which the upper end is curved together with the incident lateral surface 141c.

The upper surface 141a of the phosphor part 141 and the upper surface 142a of the surrounding part 142 form a single continuous flat surface. The lower surface 141b of the phosphor part 141 and the lower surface 142b of the surrounding part 142 form a single continuous flat surface.

In the example illustrated, the surrounding part 142 further includes a protruded part 142t. At a side above the incident lateral surface 141c, the protruded part 142t protrudes outward from the incident lateral surface 141c in the direction perpendicular to the incident lateral surface 141c away from the phosphor part 141.

The protruded part 142t includes a portion of the upper surface 142a, some of the outer lateral surfaces, and one of the lower surfaces of the surrounding part 142. The lower surface that constitutes the protruded part 142t is a lower surface different from the lower surface 142b of the surrounding part 142. The outer lateral surfaces constituting the protruded part 142t include a protruded surface 142d which faces in the same direction as that of the incident lateral surface 141c and the connection surface 142c.

For a base material of the phosphor part 141, an inorganic material that is resistant to degradation attributable to light irradiation is preferably used as the main material of the base material. Examples of the main material include ceramics. Examples of ceramics include aluminum oxide, aluminum nitride, silicon oxide, yttrium oxide, zirconium oxide, or magnesium oxide. The main material used as the base material of the phosphor part 141 is not limited to ceramics, and other examples include sapphire and quartz. The term “main material” of a constituent element as used herein refers to the material that has the highest percentage in terms of weight or volume in the constituent element. This may include the case in which a constituent element is formed only of a main material.

The phosphor part 141 can be formed, for example, by sintering a phosphor and a light transmissive material such as aluminum oxide. The amount of the phosphor contained can be set to 0.05 vol % to 50 vol % of the total volume of the ceramic material. Alternatively, for example, a ceramic made by sintering phosphor powder, substantially made only of the phosphor, may be used. The phosphor part 141 may be made of a single-crystal phosphor.

Examples of phosphors include cerium-activated yttrium aluminum garnet (YAG), cerium-activated lutetium aluminum garnet (LAG), europium-activated silicate ((Sr,Ba)₂SiO₄), α-SiAlON phosphors, β-SiAlON phosphors, or the like. Among these, YAG phosphors are highly heat resistant.

The surrounding part 142 is, for example, a sintered body formed using a ceramic as a main material. Examples of ceramics used as the main material include aluminum oxide, aluminum nitride, silicon oxide, yttrium oxide, zirconium oxide, magnesium oxide, and the like. The surrounding part 142 does not have to use a ceramic as a main material. The surrounding part 142 may be formed using, for example, a metal, ceramic-metal composite, resin, or the like.

The wavelength conversion member 140 may be obtained by integrally forming a phosphor part 141 and a surrounding part 142 as a single body. The phosphor 141 and the surrounding part 142 may be separately formed and then bonded together to form the wavelength member 140. The phosphor part 141 and the surrounding part 142 are formed integrally, for example, as a sintered body. For example, a sintered body of the phosphor part 141 is formed, and then a sintered body of enclosing part 142 is formed by sintering integrally with the phosphor part 141, so that an integrally-formed sintered body can be obtained.

The shape of and the main materials for the wavelength conversion member 140 have been explained thus far, but the wavelength conversion member 140 is not limited to these. In the present specification, the “light incident surface of the wavelength conversion member” refers to the incident lateral surface 141c of the phosphor part 141 and the connection surface 142c of the surrounding part 142 as a whole, and the “light emission surface (upper surface) of the wavelength conversion member” refers to the upper surface 141a of the phosphor part 141 and the upper surface 142a of the surrounding part 142 as a whole. Similarly, the “lower surface of the wavelength conversion member” refers to the lower surface 141b of the phosphor part 141 and the lower surface 142b of the surrounding part 142 as a whole. These do not apply to the case in which the wavelength conversion member 140 is made only of a phosphor part 141.

### Protective Device 150

A protective device 150 is a constituent element for protecting a light emitting element such as a semiconductor laser element. For example, the protective device 150 is a constituent element for preventing flow of excessive current through a specific element such as a semiconductor laser element and thus preventing destruction of the element. For the protective device 150, for example, a Zener diode made of Si can be used. For example, the protective element 150 may be a constituent element for measuring the temperature so as not to allow a specific element to fail under certain temperature conditions. For such a temperature measuring element, a thermistor can be used. A temperature measuring element is preferably positioned near the emission surface of the light emitting element 120.

### Lens Member 160

A lens member 160 has a lens incident surface 161 on which light is to be incident and a lens emission surface 162 through which the light is to exit. In the example illustrated, the lens incident surface 161 has a flat shape. The lens incident surface 161 does not have a curved shape. The lens emission surface 162 has a curved shape and a flat shape. In the example illustrated, the lens member 160 has a lens part 160A which has a curved shape and a flat part 160B which has a flat shape. The lens part 160A includes at least a portion of the curved shape of the lens emission surface 162. The lens part 160A does not include the lens incident surface 161. The flat part 160B includes the lens incident surface 161. The flat part 160B includes at least a portion of the lens emission surface 162.

When viewed from above in a direction normal to the lens incident surface 161, the flat part 160B encloses the outline of the lens part 160A. The lens part 160A is defined by the plane overlapping and parallel to the flat surface of the lens emission surface 162 and the curved surface of the lens emission surface 162. The flat part 160B is defined by the lens incident surface 161, the one or more lateral surfaces that meet the lens incident surface 161, and the plane overlapping and parallel to the flat surface of the lens emission surface 162. In the normal direction, the length of the lens part 160A is larger than the length of the flat part 160B. The length of the lens part 160A as used herein refers to the length from the flat surface of the lens emission surface 162 to the point in the curved surface of the lens emission surface 162 that is furthest from the flat surface of the lens emission surface 162 in the normal direction. The lens member 160 can be a collimating lens that collimates the light incident on the lens incident surface 161. The lens member 160 is not limited to a collimating lens, and may be a condensing lens that collects the incident light. The lens member 160 is formed with a light-transmissive material such as glass, plastic, resin, or the like.

The shape of and the material for the lens member 160 have been described thus far, but the shape and the material are not limited to those described above. As in the variation to be described later, the lens member 160 may be shaped to have no flat part, or the lens incident surface may include a curved shape.

### Wire 170

Each of the wires 170 is made of a linear shaped conductor having bonding parts at both ends. In other words, the wire 170 has bonding parts at both ends of its linear portion for bonding to other constituent elements. The wire 170 is used for electrically connecting two constituent elements. For each wire 170, for example, a metal wire can be used. Examples of metals include gold, aluminum, silver, copper, tungsten, and the like.

### Bonding Member 180

The bonding member 180 is a light transmissive member and is, for example, a light transmissive adhesive. The term “light transmissive” used herein refers to having a light transmittance of 50% or higher with respect to the light having a specific wavelength. Examples of the bonding members 180 include adhesives, such as ultraviolet-curing resins, thermosetting resins, and the like. For an ultraviolet-curing resin, an adhesive made of an epoxy-based resin or acrylate-based resin can be used. For a thermosetting resin, an adhesive made of an epoxy-based resin or silicone-based resin can be used.

### Light Emitting Device 100

A light emitting device 100 will be explained next with reference to FIG. 1 to FIG. 10.

In a light emitting device 100, a light emitting element 120 and a wavelength conversion member 140 are disposed on the upper surface 111a of the base 111. In the example illustrated, the light emitting element 120 is disposed on the upper surface 111a via a submount 130. The wavelength conversion member 140 is disposed on the upper surface 111a via a submount 135. The wavelength conversion member 140 is disposed such that its light incident surface faces the emission surface 120a of the light emitting element 120. More specifically, the incident lateral surface 141c of the phosphor part 141 faces the emission surface 120a. In the example illustrated, the flat surface portion of the incident lateral surface 141c parallels the emission surface 120a. In the case in which the incident lateral surface 141c has a curved portion, the curved portion does not have to parallel the emission surface 120a.

In the third direction Z perpendicular to the upper surface 111a of the base 111, the lower surface of the wavelength conversion member 140 is positioned lower than the lower surface of the light emitting element 120. In other words, in the third direction Z, the thickness of the submount 130 is larger than the thickness of the submount 135. With a such structure in which components are disposed on the submounts of different heights, of light emitted from the light emitting element, a portion traveling downwards can also enter the phosphor part 141 efficiently. The submounts 130 and 135 are bonded to the upper surface 111a via a metal adhesive, for example. Furthermore, a lens member 160 is disposed above the wavelength conversion member 140.

The light emitting device 100 further includes a frame part that collectively surrounds the light emitting element 120, the wavelength conversion member 140, the lens member 160. The base 111 and the frame part form a sealed space in which the light emitting element 120, the wavelength conversion member 140, and the lens member 160 are arranged. In the example illustrated, the light emitting element 120, the wavelength conversion member 140, and the lens member 160 are arranged in the sealed space that is created by the base 111, lateral part 112, and the cover 113. With the lens member 160 disposed in the sealed space in which the light emitting element 120 and the wavelength conversion member 140 are disposed, the light emitting device 100 can have a relatively simple structure. Furthermore, with the lens member 160 disposed in the sealed space, the lateral part 112 is provided so as to have a larger height in the third direction Z. This allows the lateral part 112 to absorb light emitted from the light emitting element 120 even when the wavelength conversion member 140 is damaged or detached, for example. Accordingly, direct emission of light from the light emitting element 120 to the outside of the light emitting device 100 can be reduced.

The lens member 160 is bonded to the wavelength conversion member 140 on the emission surface side of the wavelength conversion member 140. More specifically, the lens incident surface 161 of the lens member 160 is bonded via a light transmissive bonding member 180. In the example shown in FIG. 9, the bonding member 180 is in contact with the entire lens incident surface 161. Moreover, the bonding member 180 is in contact with the upper surface of the wavelength conversion member 140 over the upper surface 141a of the phosphor part 141 and the upper surface 142a of the surrounding part 142 in the upper surface of the wavelength conversion member 140. The bonding member 180 does not have to be in contact with the entirety of the lens incident surface 161. In the variation shown in FIG. 10, the bonding member 180 of the light emitting device 101 is in contact only with the peripheral part of the lens incident surface 161. The bonding member 180 is disposed on the upper surface 142a of the surrounding part 142 in the upper surface of the wavelength conversion member 140. The bonding member 180 is not disposed on the upper surface 141a of the phosphor part 141. In other words, the bonding member 180 is in contact with the upper surface 142a, but not in contact with the upper surface 141a.

As shown in FIG. 8 and FIG. 9, the outline of the lens incident surface 161 of the lens member 160 is enclosed by the upper surface of the wavelength conversion member 140 when viewed from above. More specifically, when viewed from above, the outline of the lens incident surface 161 encloses the outline of the upper surface 141a of the phosphor part 141. When viewed from above, the lens incident surface 161 overlaps at least a portion of the upper surface of the surrounding part 142. Furthermore, when viewed from above, the upper surface 142a of the enclosing part 142 encloses the outline of the lens incident surface 161. The surrounding part 142 is joined with the lens member 160 at the protruded part 142t. Furthermore, when viewed from above, the lens part 160A encloses the upper surface 141a of the phosphor part 141. When viewed from above, the lens part 160A overlaps at least one portion of the upper surface 142a of the surrounding part 142.

When viewed from above, the outline of the lens incident surface 161 of the lens member 160 is not enclosed by the lower surface of the wavelength conversion member 140. Similarly, the outline of the lens part 160A is not enclosed by the lower surface of the wavelength conversion member 140 when viewed from above. When viewed from above, the lens part 160A encloses the lower surface 141b of the phosphor part 141. The lens part 160A overlaps a portion of the lower surface 142b of the surrounding part 142 when viewed from above.

The incident lateral surface 141c of the phosphor part is positioned in the first direction X between a plane coinciding with and parallel to the emission surface 120a of the light emitting element 120 and a plane coinciding with the lens optical axis OB of the lens member 160 and parallel to the emission surface 120a. In the first direction X, moreover, a plane coinciding with and parallel to the protruded surface 142d of the phosphor part intersects with the light emitting element 120.

When viewed from above, the lens member 160 entirely overlaps the upper surface 141a of the phosphor part 141 and the upper surface 142a of the surrounding part 142. In other words, when viewed from above, the flat part 160B of the lens member 160 overlaps the upper surface 141a and the upper surface 142a. When viewed from above, moreover, the lens part 160A of the lens member 160 overlaps the upper surface 141a and the upper surface 142a. The straight line coinciding with the lens optical axis of the lens member 160 passes through the upper surface 141a and the lower surface 141b of the phosphor part.

When viewed from above, the area of overlap between the lens part 160A and the upper surface 141a of the phosphor part 141 is larger than the area of overlap between the lens part 160A and the upper surface 142a of the surrounding part 142. When viewed from above, the area of overlap between the entire lens member 160 and the upper surface 141a is smaller than the area of overlap between the entire lens member 160 and the upper surface 142a. In other words, when viewed from above, the area of overlap between the flat part 160B and the upper surface 141a is smaller than the area of overlap between the flat part 160B and the upper surface 142a. When viewed from above, the lens member 160 overlaps the entire lower surface 141b of the phosphor part 141 and at least a portion of the lower surface 142b of the surrounding part 142. Furthermore, when viewed from above, the lens part 160A overlaps the entire lower surface 141b and at least a portion of the lower surface 142b. When viewed from above, the area of overlap between the lens part 160A and the lower surface 141b of the phosphor part 141 is smaller than the area of overlap between the lens part 160A and the upper surface 141a of the phosphor part 141. When viewed from above, the area of overlap between the lens part 160A and the lower surface 141b of the phosphor part 141 is, for example, 95% or less of the area of overlap between the lens part 160A and the upper surface 141a of the phosphor part 141. When viewed from above, moreover, the area of overlap between the lens part 160A and the upper surface 141a without overlapping the lower surface 141b is 5% or more of the area of overlap between the lens part 160A and both the upper surface 141a and the lower surface 141b.

The light emitting element 120 emits light toward a lateral side thereof (i.e., the light is emitted laterally from a lateral surface of the light emitting element 120). In the example illustrated, it emits light such that the light travels in the positive first direction X. The light emitted from the light emitting element 120 toward a lateral side thereof enters the light incident surface of the wavelength conversion member 140. Furthermore, the light that entered the wavelength conversion member 140 undergoes wavelength conversion and is then emitted from the light emission surface of the wavelength conversion member 140. In this example, a plane coinciding with and parallel to the light incident surface intersects with a plane coinciding with and parallel to the light emission surface. The shape of the light incident surface differs from the shape of the light emission surface. Furthermore, the shape of the incident lateral surface 141c of the phosphor part 141 differs from the shape of the upper surface 141a of the phosphor part 141. The area of the incident lateral surface 141c differs from the area of the upper surface 141a, the area of the upper surface 141a being equal to or greater than twice the area of the incident lateral surface 141c. The light that exited upwards from the light emission surface enters the lens member 160. More specifically, the light exiting the upper surface 141a enters the lens incident surface 161 of the lens member 160.

The light that entered the lens incident surface 161 of the lens member 160 exits the lens emission surface 162. The light that exited the lens emission surface 162 passes through the frame part to the outside of the light emitting device 100. More specifically, the light that exited the lens emission surface 162 enters the lower surface 113b of the cover 113 and exits through the upper surface 113a. The area of the irradiation region in the upper surface 113a of the cover 113 is equal to or less than 1.5 times the area of the irradiation region in the lower surface 113b.

When viewed from above, the emission surface 120a of the light emitting element 120 overlaps the surrounding part 142 of the wavelength conversion member 140. More specifically, when viewed from above, the emission surface 120a overlaps the protruded part 142t of the surrounding part 142. The emission surface 120a overlaps the lens member 160. In the example illustrated, the emission surface 120a also overlaps the lens part 160A and the flat part 160B.

In the direction perpendicular to the upper surface 111a of the base 111 (the third direction Z), the upper surface 114a of the first stepped part 114 (or the upper surface 115a of the second stepped part 115) is positioned higher than the lens incident surface 161 of the lens member 160. Furthermore, the upper surface 114a of the first stepped part 114 (or the upper surface 115a of the second stepped part 115) is positioned lower than the lens emission surface 162. The difference between the length of the lens member 160 and the distance from the lens incident surface 161 to the lower surface 113b in the third direction Z is, for example, 300 μm or smaller. The difference is desirably 150 μm or smaller in order to reduce the size of the light emitting device 100. The length of the lens member 160 in the third direction Z can be equal to or smaller than one half of the length of the sealed space (distance from the upper surface 111a of the base 111 to the lower surface 113b of the cover 113).

In the direction of the optical axis of light emitted from the light emitting element 120 (the first direction X), the length of the lens member 160 is smaller than the length of the upper surface of the wavelength conversion member 140. In the first direction X, the length of the lens member 160 is larger than the length of the lower surface of the wavelength conversion member 140. In the first direction X, the size of the lens member 160 is equal to or smaller than 0.5 times the distance between the opposing inner lateral surfaces.

In the example illustrated, the optical axis of light emitted from the light emitting element 120 is denoted as OA. When viewed from above, the lens member 160 may have line symmetry with the optical axis OA serving as the line of symmetry. When viewed from above, the wavelength conversion member 140 may have line symmetry with the optical axis OA serving as the line of symmetry. The direction of the optical axis OA parallels the first direction X. Similarly, the lens part 160A can have line symmetry with the optical axis OA serving as the line of symmetry. The upper surface 141a of the phosphor part 141 can have line symmetry with the optical axis OA serving as the line of symmetry.

When viewed from above, the submount 130 is not disposed to have line symmetry with the optical axis OA serving as the line of symmetry. More specifically, the submount 130 is disposed on the positive side of the second direction Y relative to the optical axis OA on the upper surface 111a of the base 111. The distance between one of the lateral surfaces of the submount 130 extending in the second direction Y and the lateral surface of the first stepped part 114 is larger than the distance between the other lateral surface of the submount 130 extending in the second direction Y and the lateral surface of the second stepped part 115. The difference between the distance from one of the lateral surfaces of the submount 130 extending in the second direction Y to the lateral surface of the first stepped part 114 and the distance from the other lateral surface of the submount 130 extending in the second direction Y to the lateral surface of the second stepped part 115 is, for example, 150 μm or larger.

The light emitting element 120 is disposed approximately in the center of the upper surface 111a of the base 111 in the second direction Y. The light emitting element 120 is disposed on the upper surface of the submount 130 near one of the two sides that extend in the second direction Y. The protective device 150 is disposed on the upper surface of the submount 130. The protective device 150 is disposed near the side of the upper surface of the submount 130 extending in the second direction Y opposite the side that is near the light emitting element 120.

A height of each of the upper surface 114a of the first stepped part 114 and the upper surface 115a of the second stepped part 115, for example, from the upper surface 111a of the base 111 is greater than a height of the upper surface of the light emitting element 120 from the upper surface 111a of the base 111. In the example illustrated, a height of each of the upper surface 114a and the upper surface 115a, for example, from the upper surface 111a of the base 111 is smaller than a height of the lens incident surface 161 of the lens member 160 from the upper surface 111a of the base 111. The distance from the upper surface of the light emitting element 120 to the upper surface 114a (or the upper surface 115a) is larger than the distance from the upper surface 114a (or the upper surface 115a) to the lens incident surface 161. The distance from the upper surface 114a (or the upper surface 115a) to the lens incident surface 161 is, for example, 300 μm or smaller.

The light emitting element 120 is electrically connected to the metal films disposed on the upper surface 114a and the upper surface 115a via wires 170. The light emitting device 100 illustrated has a plurality of wires 170. The plurality of wires 170 include a wire 170 bonded at one end to the upper surface 114a and at the other end to the upper surface of the light emitting element 120. They also include a wire bonded at one end to the upper surface of the protective device 150 and at the other end to the upper surface 114a. They further include a wire 170 bonded at one end to the upper surface 115a and at the other end to the top of the submount 130. In the example illustrated, the length of the wire 170 bonded to the upper surface 114a is larger than the length of the wire 170 bonded to the upper surface 115a.

For the electrical connection of the light emitting element 120 to an external power source, the metal film disposed on the lower surface 111b of the base 111 and/or the first lower surface 112b of the lateral part 112 can be utilized. This allows for electrically connecting the light emitting element 120 and the external power supply via the metal film on the lower surface 111b and/or the first lower surface 112b that is electrically connected, via the metal material disposed in the via holes, to the metal film disposed on the upper surface 114a and/or the upper surface 115a.

The cover 113 has a light transmitting region which allows the light to exit the lens emission surface 162 to the outside. The lower surface 113b of the cover 113 is the incident surface in its entirety, and the entire cover 113 may constitute the light transmitting region. The light transmitting region of the cover 113 is preferably configured to transmit 50% or more, more preferably 70% or more of the light that exits the lens emission surface 162 of the lens member 160. The cover 113 may partially have a light transmitting region. The lower surface 113b of the cover 113 may be provided with a light shielding film in the region other than the light irradiation region on which the light from the lens member 160 is to be irradiated. For the light shielding film, for example, a metal film is disposed. Similarly, a light shielding film may be disposed on the upper surface 113a.

### Second Embodiment

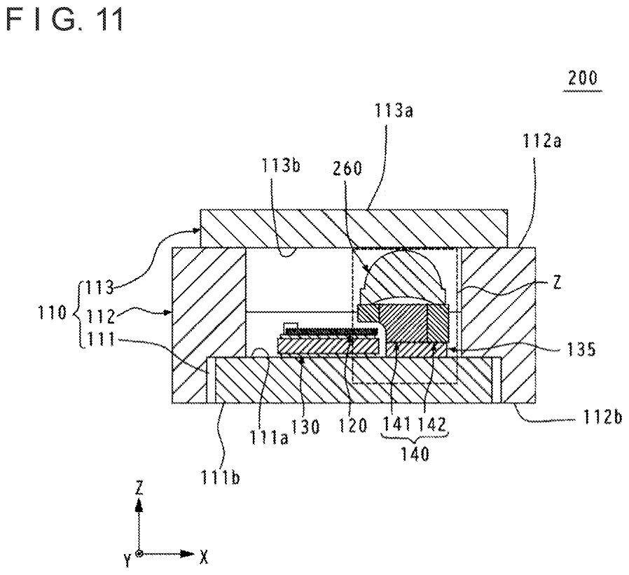

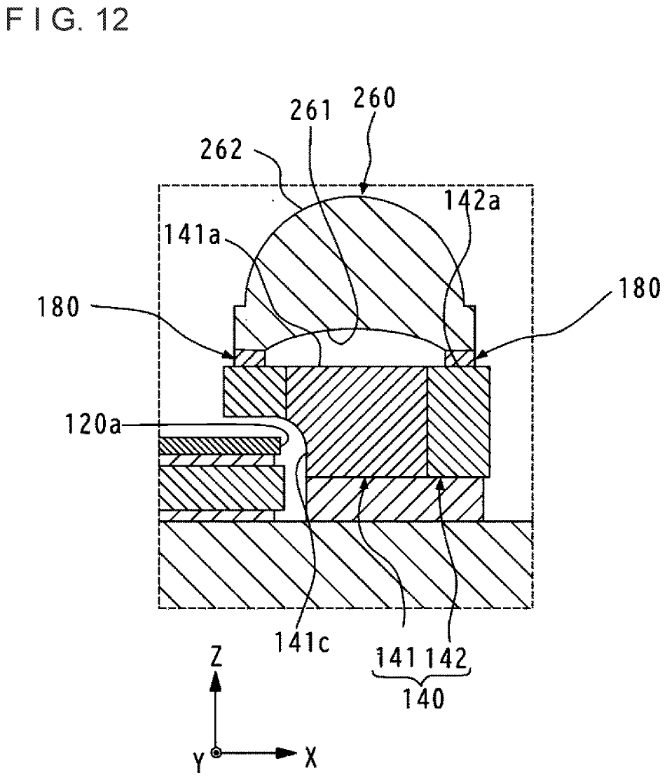

A light emitting device 200 according to a second embodiment will be explained with reference to FIG. 1, FIG. 11, and FIG. 12. FIG. 1 is a schematic perspective view of the light emitting device 200 according to the second embodiment. FIG. 11 is a schematic cross-sectional view of the light emitting device 200 taken along line XI-XI in FIG. 1. FIG. 12 is a schematic enlarged cross-sectional view enlarging the portion Z in FIG. 11. For reference purposes, the X-axis, Y-axis, and Z-axis that are orthogonal to one another are provided in FIG. 11 and FIG. 12. The directions parallel to the X-axis, the Y-axis, and the Z-axis are designated as the first direction X, the second direction Y, and the third direction Z, respectively.

As shown in the drawings, the light emitting device 200 differs from the light emitting device 100 at least in including a lens member 260, in place of the lens member 160, in which the lens incident surface 261 includes a curved shape. The differences between the light emitting device 200 and the light emitting device 100 will mainly be explained below, while omitting the common features as appropriate.

### Lens Member 260

A lens member 260 has a lens incident surface 261 and a lens emission surface 262. The lens incident surface 261 has a curved shape. In the example illustrated, the lens incident surface 261 of the lens member 260 has a flat shape and a curved shape. The incident surface 271 has a flat shape in its peripheral portion, and a curved shape at a location inward thereof. The curved shape of the lens incident surface 261 is recessed towards the lens emission surface 262 relative to the flat shape. The lens emission surface 262 has a curved shape. The lens emission surface 262 does not have a flat shape. The lens emission surface 262 may partially include a flat shape.

### Light Emitting Device 200

Similar to the lens member 160 of the light emitting device 100, the lens member 260 of the light emitting device 200 is disposed above the wavelength conversion member 140. The lens member 260 is bonded to the upper surface of the wavelength conversion member 140 via a bonding member 180 on the lens incident surface side. The bonding member 180 is in contact with the flat shape portion of the lens incident surface 261. The bonding member 180 is not in contact with the curved shape portion of the lens incident surface 261. The bonding member 180 is in contact with the upper surface 142a of the surrounding part 142 of the wavelength conversion member 140. The bonding member 180 is not in contact with the upper surface 141a of the phosphor part 141. There is a space between the lens incident surface 261 of the lens member 260 and the phosphor part 141 of the wavelength conversion member 140.

When viewed from above, the lens incident surface 261 overlaps the upper surface 141a of the phosphor part 141 and the upper surface 142a of the surrounding part 142. When viewed from above, the curved shape portion of the lens incident surface 261 overlaps the upper surfaces 141a and 142a. When viewed from above, the flat shape portion of the lens incident surface 261 overlaps the upper surface 142a. When viewed from above, the flat shape portion of the lens incident surface 261 does not overlap the upper surface 141a.

The thickness of the space between the upper surface of the wavelength conversion member 140 and the curved shape portion of the lens incident surface 261 in the third direction Z is not constant in a side view viewing in the second direction Y. In this side view, the length of the space in the third direction Z is largest at the straight line coinciding the optical axis of the lens member 260. The curvature of the curved shape portion of the lens incident surface 261 differs from the curvature of the curved shape of the lens emission surface 262. More specifically, the curvature of the curved shape portion of the lens incident surface 261 is smaller than the curvature of the curved shape of the lens emission surface 262. The length of the central portion of the lens member 260 in the third direction Z in the side view is larger than the length at the peripheral portion of the lens member 260. In the third direction Z, the point in the lens incident surface 261 that intersects with the lens optical axis OB is positioned lower than the flat shape portion of the lens emission surface 262.

Similarly to the light emitting device 100, the light that exited the upper surface of the wavelength conversion member 140 in the light emitting device 200 enters the lens incident surface 261 of the lens member 260. In this example, with the lens incident surface 261 having a curved shape, the angle of incidence of light emitted from the phosphor part 141 can be reduced not only in the vicinity of the center, but also at the peripheral portion of the lens incident surface 261. This can reduce the reflection of the incident light at the peripheral portion of the lens incident surface 261.

### Third Embodiment

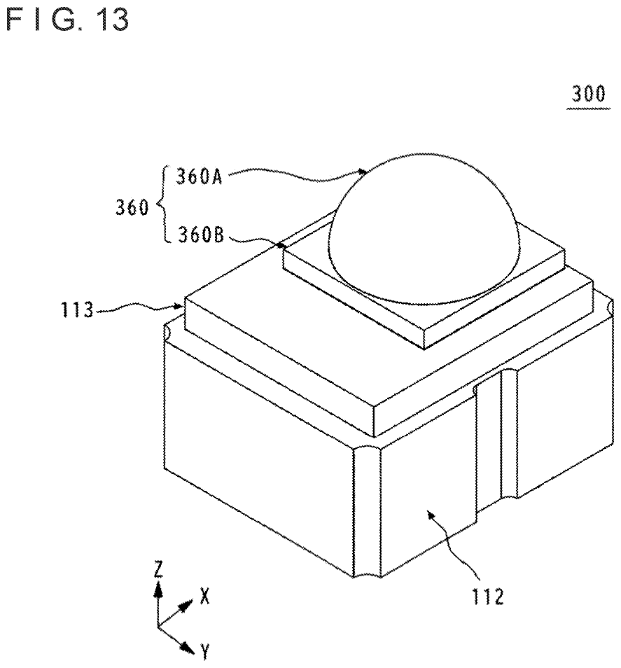

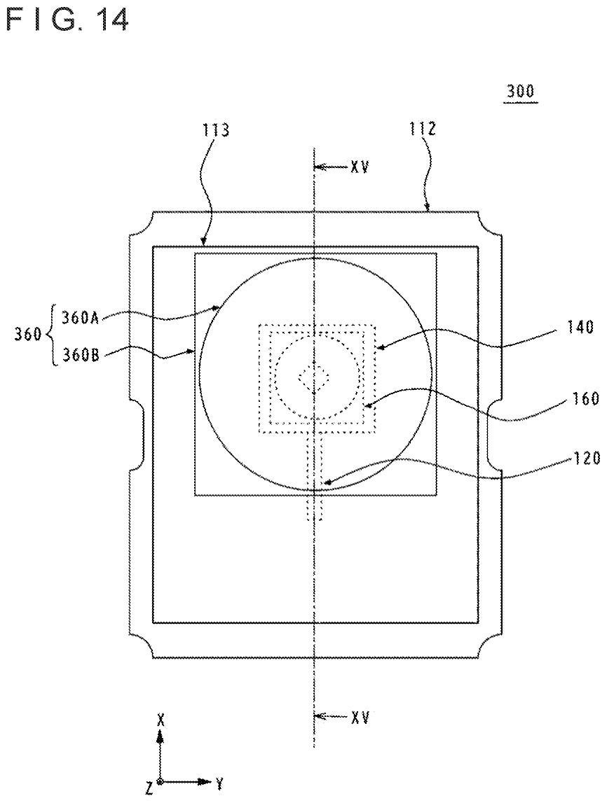

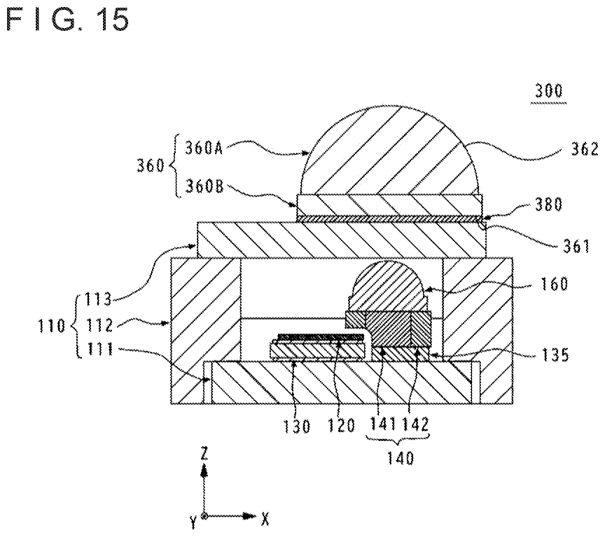

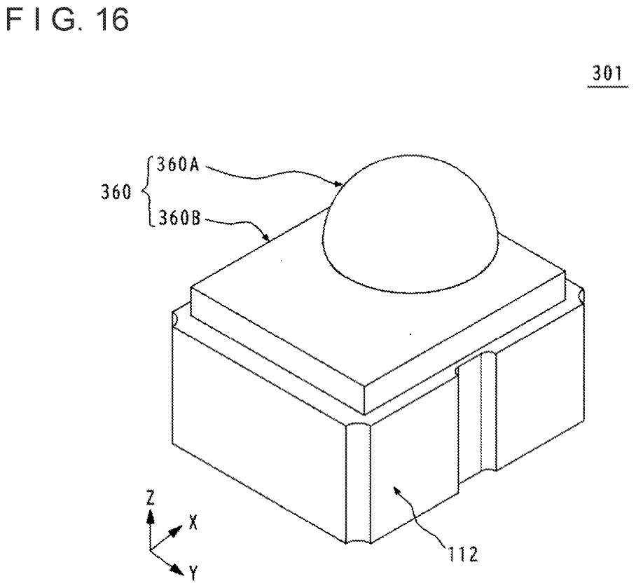

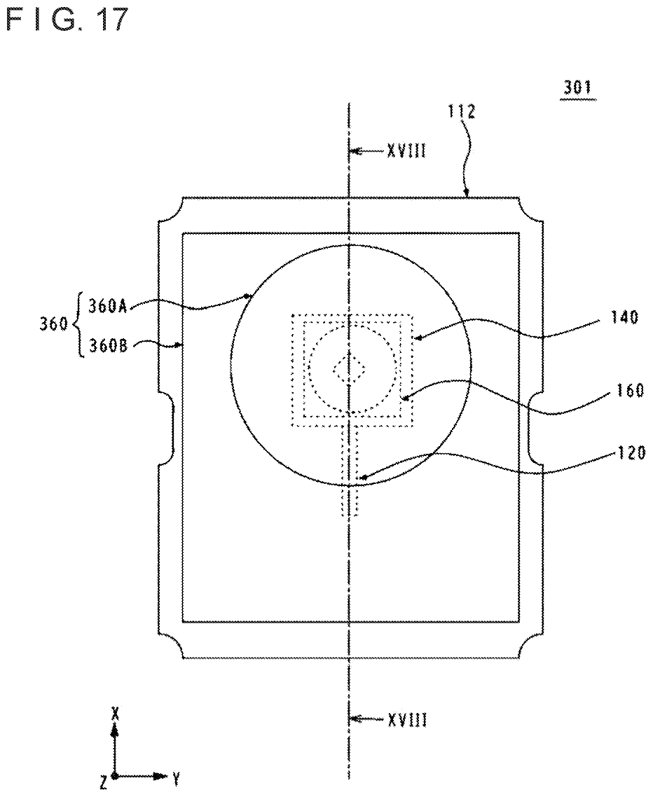

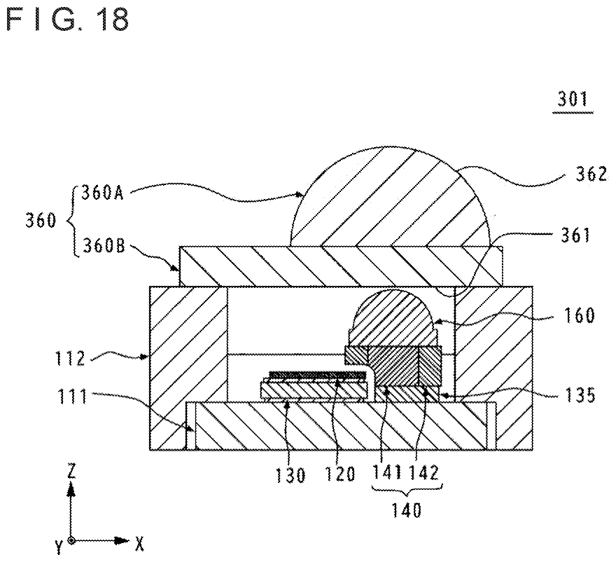

Light emitting devices 300 and 301 according to a third embodiment will be explained with reference to FIG. 13 to FIG. 18. FIG. 13 is a schematic perspective view of the light emitting device 300. FIG. 14 is a schematic top view of the light emitting device 300 shown in FIG. 13. FIG. 15 is a schematic cross-sectional view of the light emitting device 300 taken along line XV-XV in FIG. 14. FIG. 16 is a schematic perspective view of the light emitting device 301 according to the third embodiment which is a variation. FIG. 17 is a schematic top view of the light emitting device 301 shown in FIG. 16. FIG. 18 is a schematic cross-sectional view of the light emitting device 301 taken along line XVIII-XVIII in FIG. 17. As a reference, X-axis, Y-axis, and Z-axis that are orthogonal to one another are provided in FIG. 13 to FIG. 18. The directions parallel to the X-axis, the Y-axis, and the Z-axis are the first direction X, the second direction Y, and the third direction Z, respectively. The first direction X and the second direction Y parallel the upper surface 111a of the base 111, and the third direction Z is perpendicular to the upper surface 111a of the base 111.

As shown in the drawings, the light emitting device 300 according to the third embodiment differs from the light emitting devices 100 and 200 at least in further including a second lens member 360 above the lens member 160. The differences between the light emitting device 300 and the light emitting devices 100 and 200 will be mainly explained, and the common features will be omitted as appropriate.

### Second Lens Member 360

Similar to the lens member 160, the second lens member 360 has a lens incident surface 361 on which light is to be incident and a lens emission surface 362 through which the light exits. In the example illustrated, the lens incident surface 361 has a flat shape. The lens incident surface 361 does not include a curved shape. The lens emission surface 362 has a curved shape and a flat shape. Furthermore, in the example illustrated, the second lens member 360 has a lens part 360A which has a lens shape and a flat part 360B which has flat shape. The lens part 360A includes at least a portion of the lens emission surface 362. The lens part 360A does not include the lens incident surface 361. The flat part 360B includes the lens incident surface 361. The flat part 360B includes at least a portion of the lens emission surface 362.

When viewed from above in a direction normal to the lens incident surface 361, the outline of the lens part 360A is enclosed by the flat part 360B. In this normal direction, the length of the lens part 360A is larger than the length of the flat part 360B. The second lens member 360, similarly to the lens member 160, can be a collimating lens that collimates the light incident on the lens incident surface 361. Moreover, the second lens member 360 can be formed of a light-transmissive material that is the same as that for the lens member 160.

### Light Emitting Device 300

The second lens member 360 is disposed on the upper surface 113a of the cover 113. More specifically, lens incident surface 361 of the second lens member is bonded to the upper surface 113a of the cover 113 via a bonding member 380. For the bonding member 380, the same material as that used as the bonding member 180 for bonding the wavelength conversion member 140 and the lens member 160 may be used. The second lens member 360 is disposed on the upper surface 113a of the cover 113 at a location closer to one of the short sides of the upper surface 113a. As shown in FIG. 14, when viewed from above, the outline of the second lens member 360 encloses the outlines of the lens member 160 and the wavelength conversion member 140. The outline of the lens part 360A of the second lens member 360 encloses the outlines of the lens member 160 and the wavelength conversion member 140. When viewed from above, the second lens member 360 overlaps a portion of the light emitting element 120.

In the first direction X, the length of the second lens member 360 is 2 to 2.5 times the length of the lens member 160. In the first direction X, the length of the second lens member 360 is 1.5 to 2 times the length of the light emitting element 120. In the first direction X, the length of the second lens member 360 is 0.5 to 0.7 times the length of the cover 113.

In the third direction Z, the length of the second lens member 360 is 2 to 2.5 times the length of the lens member 160. In the third direction Z, the length of the second lens member 360 is 2.5 to 3.0 times the length of the wavelength conversion member 140. In the third direction Z, the length of the second lens member 360 is larger than the distance from the upper surface 111a of the base 111 to the lower surface 113b of the cover 113. In the third direction Z, the length of the lens part 360A of the second lens member 360 is smaller than the distance from the upper surface 111a of the base 111 to the lower surface 113b of the cover 113.

Using two lens members as described above can improve the optical control accuracy and efficiency by way of collimation or the like. In the example illustrated, the lens member 160 is disposed in the sealed space the lens part 160A and the second lens member 360 on the outside of the sealed space of the light emitting device 300. The lens member 160 controls light at a position that is in close proximity to the wavelength conversion member 140, so that the size of the lens member can be relatively small. Disposing the second lens member 360 on the outside of the sealed space rather than the inside the sealed space allows for securely creating a sealed space without allowing the sealed space to increase in size in the third direction Z. Preventing the increase in size of the sealed space allows for reducing the movement of the wavelength conversion member 140 in the sealed space in the event that the wavelength conversion member 140 becomes detached or the like.

### Variation

A light emitting device 301, a variation, according to the third embodiment will be explained next with reference to FIG. 16 to FIG. 18. The light emitting device 301 differs from the light emitting device 300 such that the second lens member 360 and the cover are integrally formed, i.e., the second lens member 360 is a sealing member. In the variation, the second lens member 360 can be considered as having a lens part integrally formed with a cover part. In the light emitting device 301, the lens part and the flat part (cover part) of the second lens member 360 are integrally formed by molding, for example.

### Second Lens Member 360

The second lens member according to the variation has a lens incident surface 361 on which light is to be incident, and a lens emission surface 362 through which light exits. In the example illustrated, the lens incident surface 361 has a flat shape. The lens incident surface 361 does not include a curved shape. The lens emission surface 362 has a curved shape and a flat shape. The second lens member 360 has a lens part 360A having a lens shape, and a flat part 360B having a flat shape. The lens part 360A includes at least a portion of the lens emission surface 362. The lens part 360A does not include the lens incident surface 361. The flat part 360B includes the lens incident surface 361. The flat part 360B includes at least a portion of the lens emission surface 362.

When the second lens member 360 is viewed from above, the area of the lens part 360A is smaller than the area of the flat part 360B excluding the lens part 360A. The length of the lens part 360A in the third direction Z is larger than the length of the flat part 360B in the third direction Z.

### Light Emitting Device 301

The second lens member 360 is bonded to the upper surface 112a of the lateral part 112 at the peripheral portion of the lens incident surface 361. In the light emitting device 301, the light emitting element 120, the wavelength conversion member 140, and the lens member 160 are arranged in the sealed space formed by the base 111, the lateral part 112, and the second lens member 360. Using the second lens member 360 as a sealing member in this manner can miniaturize the light emitting device 301 as a whole in the three directions.

### Fourth Embodiment

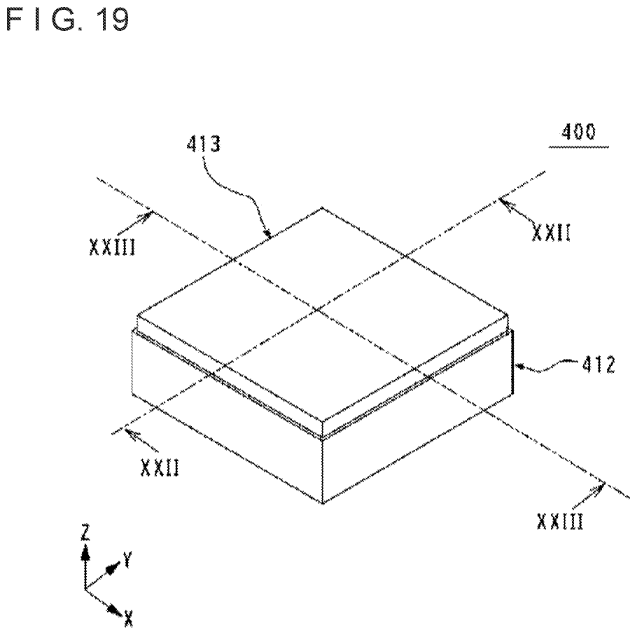

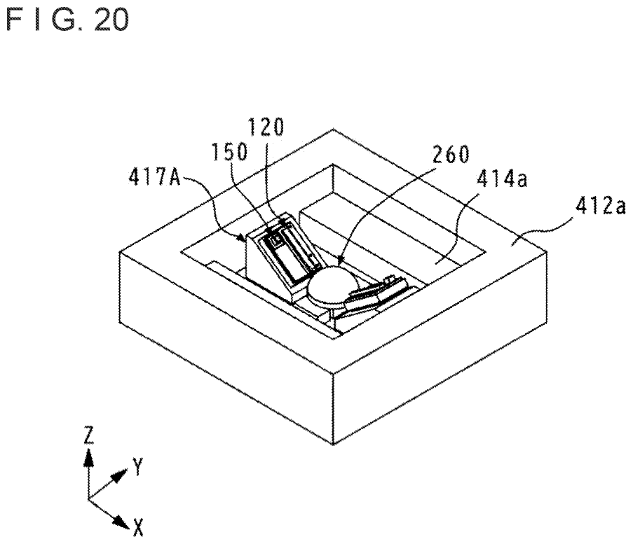

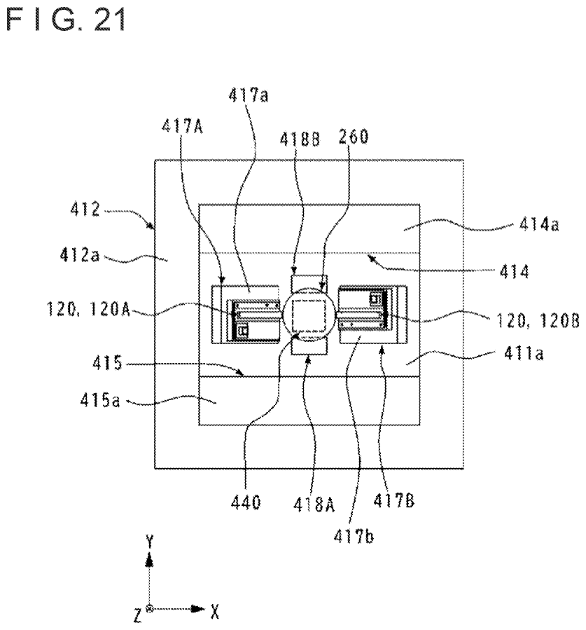

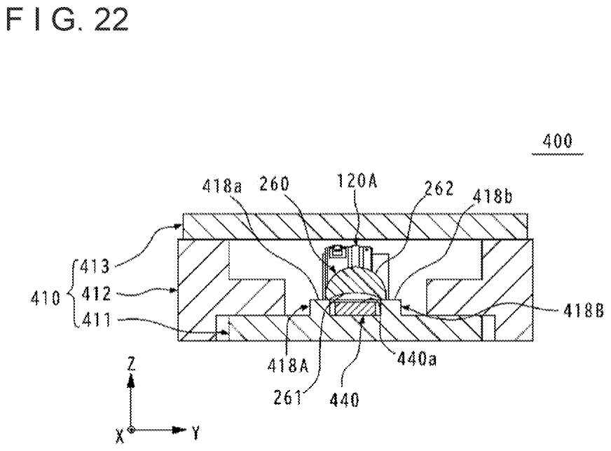

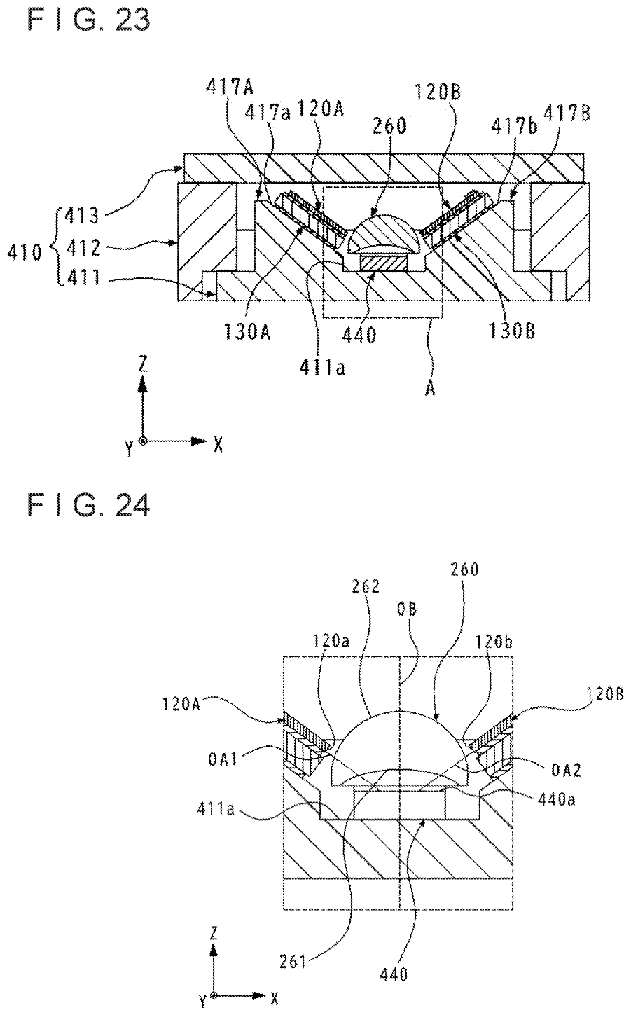

A light emitting device 400 according to a fourth embodiment will be explained with reference to FIG. 19 to FIG. 24. FIG. 19 is a schematic perspective view of the light emitting device 400. FIG. 20 is a schematic perspective view showing the light emitting device 400 in FIG. 19 without the cover 413. FIG. 21 is a schematic top view corresponding to FIG. 20. FIG. 22 is a schematic cross-sectional view of the light emitting device 400 taken along line XXII-XXII in FIG. 19. FIG. 23 is a schematic cross-sectional view of the light emitting device 400 taken along line XXIII-XXIII in FIG. 19. FIG. 24 is a schematic enlarged cross-sectional view enlarging the portion A in FIG. 23. In FIG. 24, the lens member 260 and the wavelength conversion member 440 are not marked with hatching in order to simplify the explanation of the imaginary lines OA1 and OA2. As a reference, X-axis, Y-axis, and Z-axis that are orthogonal to one another are provided in FIG. 19 to FIG. 24. The directions parallel to the X-axis, the Y-axis, and the Z-axis are the first direction X, the second direction Y, and the third direction Z, respectively. The first direction X and the second direction Y parallel the upper surface 411a of the base 411, and the third direction Z is perpendicular to the upper surface 411a of the base 411.

The light emitting device 400 in the fourth embodiment differs from the light emitting devices of the other embodiments at least in including a first protruded part 417A where the light emitting element 120 is disposed, and light emitted from the light emitting element 120 enters the upper surface of the wavelength conversion member 440. In the description below, configurations of the light emitting device 400 different from the light emitting devices 100, 200, and 300 will be mainly explained below, while description of configurations that are the same as those of the light emitting devices 100, 200, and 300 may be omitted as appropriate.

### Package 410

As shown in FIG. 22 and FIG. 23, a package 410 includes a base 411, a lateral part 412, and a cover 413. The base 411 has one or more protruded parts. For example, the base 411 can have a plurality of protruded parts having different shapes. In the example illustrated, the base 411 includes a first protruded part 417A, a second protruded part 417B, a third protruded part 418A, and a fourth protruded part 418B. The first protruded part 417A and the second protruded part 417B have the same shape, and the third protruded part 418A and the fourth protruded part 418B have the same shape.

The first protruded part 417A will be explained first. The first protruded part 417A has an upper surface and several lateral surfaces. The lateral surfaces include an oblique surface 417a oblique to the upper surface 411a of the base. The oblique surface 417a is, for example, at an angle of 45 degree with respect to the upper surface 411a. The oblique angle is not limited to 45 degrees. Among the surfaces of the first protruded part 417A, the oblique surface 417a has the largest area. Setting the area of the oblique surface 417a in this manner can facilitate the disposition of the light emitting element 120 on the oblique surface to be described later.

As shown in FIG. 21, the base 411 is further provided with a second protruded part 417B. The second protruded part 417B may have the same shape and size as those of the first protruded part 417A. The first protruded part 417A and the second protruded part 417B are disposed such that the oblique surface 417a of the first protruded part 417A faces the oblique surface 417b of the second protruded part 417B in the first direction X. When viewed from above, the oblique surfaces 417a and 417b are both larger in length in the first direction X than in the second direction Y. In a side view in the first direction X, a large portion of the first protruded part 417A and a large portion of the second protruded part 417B overlap with each other. In a side view in the second direction Y, the first protruded part 417A and the second protruded part 417B do not overlap.

Next, a third protruded part 418A will be explained with reference to FIG. 21 and FIG. 22. The third protruded part 418A has an upper surface 418a and a plurality of lateral surfaces. The upper surface 418a of the third protruded part 418A is, for example, a flat surface parallel to the upper surface 411a of the base, and the lateral surfaces of the third protruded part 418A are flat surfaces perpendicular to the upper surface 411a. The upper surface 418a can have the largest area among the surfaces the third protruded part 418A possesses. This allows for facilitating disposing of the lens member 160 described later on the upper surface.

In the example illustrated, the base 411 further includes a fourth protruded part 418B. The fourth protruded part 418B can have the same shape and size as those of the third protruded part 418A. Furthermore, the third protruded part 418A and the fourth protruded part 418B have shapes and sizes different from those of the first protruded part 417A (or the second protruded part 417B). The third protruded part 418A and the fourth protruded part 418B are disposed such that a lateral surface of the third protruded part 418A faces a lateral surface of the fourth protruded part 418B in the second direction Y. The upper surfaces 418a and 418b of the third protruded part 418A and the fourth protruded part 418B are both larger in length in the first direction X than in the second direction Y. In a side view from the first direction X, the third protruded part 418A and the fourth protruded part 418B do not overlap. Furthermore, in a side view in the second direction Y, a large portion of the third protruded part 418A and a large portion of the fourth protruded part 418B overlap with each other.

The first protruded part 417A and the second protruded part 417B are larger in length in the first direction X than the third protruded part 418A and the fourth protruded part 418B. The first protruded part 417A and the second protruded part 417B are larger in length in the second direction Y than the third protruded part 418A and the fourth protruded part 418B.

In the first direction X, the length of the third protruded part 418A (or the fourth protruded part 418B) is smaller than the shortest distance from the first protruded part 417A to the second protruded part 417B. In the second direction Y, the shortest distance from the third protruded part 418A to the fourth protruded part 418B is smaller than the length of the first protruded part 417A (or the second protruded part 417B). Furthermore, in the second direction Y, the distance between the point in the third protruded part 418A furthest from the fourth protruded part 418B and the point in the fourth protruded part 418B furthest from the third protruded part 418A is larger than the length of the first protruded part 417A (or the second protruded part 417B). When viewed from above, the third protruded part 418A and the fourth protruded part 418B are positioned in the region between the first protruded part 417A and the second protruded part 417B with respect to the first direction X.

The lateral part 412, similarly to the light emitting device 100 according to the first embodiment, is connected to the upper surface 411a of the base 411 and extends upwards from the upper surface 411a. The lateral part 412 has an upper surface 412a, one or more lower surfaces, one or more inner lateral surfaces, and one or more outer lateral surfaces. The upper surface 412a of the lateral part 412 meets with the one or more outer lateral surfaces. The outer perimeter shape of the upper surface 412a is, for example, rectangular. The inner perimeter shape of the upper surface of the upper surface 412a is, for example, rectangular. The one or more inner lateral surfaces of the lateral part 412 meet with the upper surface 411a of the base 411.

The lateral part 412 includes a stepped portion projecting inward. Specifically, the lateral part 412 has a first stepped part 414 or/and a second stepped part 415 when viewed from above. In the example illustrated, when viewed from above, the lateral part 412 has an upper surface 414a and an upper surface 415a along respective ones of the two sides of the inner perimeter shape of the upper surface 412a that extend in the first direction X. In other words, when viewed from above, the first stepped part 414 and the second stepped part 415 are disposed to face each other in the second direction Y. As described above, the stepped portions are disposed to face each other in a direction in which the third protruded part 418A and the fourth protruded part 418B face each other, with a distance across which the third protruded part 418A and the fourth protruded part 418B face each other being relatively shorter than a distance across which the first protruded part 417A and the second protruded part 417B faces each other. Disposing them in this manner allows for preventing an increase in size of the package 410 in one direction when viewed from above.

The upper surfaces 414a and 415a of the stepped parts 414 and 415 are positioned lower than the highest point of the first protruded part 417A (or the second protruded part 417B) and higher than the upper surface of the third protruded part 418A (or the fourth protruded part 418B). Moreover, the upper surface 414a and the upper surface 415a can be in parallel with the upper surface 411a of the base 411, for example.

As shown in the drawings, the cover 413 has an upper surface, a lower surface, and one or more lateral surfaces that meet the upper surface and the lower surface. The one or more lateral surfaces connect the outer perimeter of the upper surface and the outer perimeter of the lower surface. The cover 413 has, for example, a rectangular-parallelepiped shape or cubic shape. In this case, both the upper surface and the lower surface of the cover 413 are rectangular, and the cover 413 has four rectangular lateral surfaces. However, the cover 413 is not limited to a rectangular-parallelepiped shape or cubic shape. In other words, the cover 413 is not limited to a rectangle when viewed from above, and can be any appropriate shape, such as a circle, ellipse, polygon, or the like.

Similarly to the light emitting device 100 according to the first embodiment, the cover 413 is supported by the lateral part 412, and positioned above the upper surface 411a of the base 411. The peripheral portion of the lower surface of the cover 413 is bonded to the upper surface 412a of the lateral part 412, for example. Bonding the cover 413 to the lateral part 412 creates a sealed space surrounded by the base 411, the lateral part 412, and the cover 413.

The base 411 can be formed by using, for example, a ceramic as a main material. For ceramics, for example, aluminum nitride, silicon nitride, aluminum oxide, or silicon carbide can be used. The lateral part 412 and the cover 413 may be formed by using the same materials as those for the lateral part 112 and the cover 113 in the light emitting device 100 according to the first embodiment.

### Wavelength Conversion Member 440

A wavelength conversion member 440, similarly to the wavelength conversion member 140 according to the first embodiment, is a member that converts the incident light of a specific wavelength into light of another wavelength. In the wavelength conversion member 440 according to this embodiment, the upper surface 440a is a light incident surface on which light is to be incident and is a light emission surface through which light exits.

In the example illustrated, the wavelength conversion member 440 has a rectangular-parallelepiped shape, and is rectangular when viewed from above. The wavelength conversion member 440 has an upper surface 440a, a lower surface, and a plurality of lateral surfaces. The wavelength conversion member 440 is a member that contains a phosphor in the entire structure, for example. For the material for forming the wavelength conversion member 440, the same materials for the phosphor part 141 of the wavelength conversion member 140 according to the first embodiment can be used. The wavelength conversion member 440 may further include a component that corresponds to the surrounding part 142 of the wavelength conversion member 140 according to the first embodiment.

### Light Emitting Device 400

In the explanation below, a light emitting device 400 having a first light emitting element 120A and a second light emitting element 120B shown in FIG. 20 to FIG. 24 will be described. However, the light emitting device 400 illustrated is an example of this embodiment, and the light emitting device 400 can be, for example, in a form of including one light emitting element 120 or in a form of including three or more light emitting elements 120.

The light emitting device 400 includes a first light emitting element 120A, a second light emitting element 120B, a wavelength conversion member 440, a lens member 260, and a package 410 in which these members are sealed. The first light emitting element 120A and the second light emitting element 120B are disposed on the first protruded part 417A and the second protruded part 417B, respectively. More specifically, they are disposed on the first protruded part 417A and the second protruded part 417B via a first submount 130A and a second submount 130B, respectively. For the first submount 130A and the second submount 130B here, the same material as that for the submount 130 according to the first embodiment can be used. Furthermore, in the example illustrated, the first submount 130A and the second submount 130B are each provided with a protective device 150.

The wavelength conversion member 440 is disposed on the upper surface 411a of the base 411. More specifically, the wavelength conversion member 440 is disposed in the region between the first protruded part 417A and the second protruded part 417B. In the example illustrated, the wavelength conversion member 440 is disposed between the first protruded part 417A and the second protruded part 417B that face each other in the first direction X. Moreover, a metal film may be disposed on the lower surface of the wavelength conversion member 440. In the third direction Z, the upper surface 440a of the wavelength conversion member 440 is positioned lower than the lowermost point of the emission surface 120a of the first light emitting element 120A (or the emission surface 120b of the second light emitting element 120B). In the example illustrated, the optical axis of light emitted from the first light emitting element 120A intersects with the upper surface 440a of the wavelength conversion member 440. The optical axis of light emitted from the second light emitting element 120B intersects with the upper surface 440a of the wavelength conversion member 440.

The wavelength conversion member 440, furthermore, is disposed between the third protruded part 418A and the fourth protruded part 418B that are positioned to oppose one another in the second direction Y. In the first direction X, the third protruded part 418A and the fourth protruded part 418B are both larger in length than the wavelength conversion member 440. In the second direction Y, moreover, the third protruded part 418A and the fourth protruded part 418B are both smaller in length than the wavelength conversion member 440. In the third direction Z, furthermore, the third protruded part 418A and the fourth protruded part 418B are both larger in length than the wavelength conversion member 440.

A lens member 260 is disposed above the wavelength conversion member 440. More specifically, the lens member 260 is disposed above the wavelength conversion member 440 by being supported by the third protruded part 418A and the fourth protruded part 418B. The lens member 260 is the same lens member as the lens member 260 according to the second embodiment. In the example illustrated, the flat portion located in the periphery of the lens incident surface 261 is bonded to the upper surface 418a of the third protruded part 418A and the upper surface 418b of the fourth protruded part 418B. In a side view, the lens incident surface 261 and the upper surface 440a of the wavelength conversion member 440 are isolated, i.e., there is a space between the two.

FIG. 24 shows an imaginary line OA1 that extends from the emission point and is perpendicular to the emission surface 120a of the first light emitting element 120A, and an imaginary line OA2 that extends from the emission point and is perpendicular to the emission surface 120b of the second light emitting element 120B. Because the light emitting elements 120 are disposed on oblique surfaces, the imaginary line OA1 and the imaginary line OA2 are oblique to the upper surface 411a of the base 411. The imaginary line OA1 and the imaginary line OA2 pass through the lens emission surface 262, the lens incident surface 261, and the upper surface 440a of the wavelength conversion member 440. On the upper surface 440a, the imaginary line OA1 is positioned closer to the first light emitting element 120A in the first direction X than the lens optical axis OB of the lens member 260 is. Similarly, on the upper surface 440a, the imaginary line OA2 is positioned closer to the second light emitting element 120B in the first direction X than the lens optical axis OB of the lens member 260 is.

The outgoing light from the first light emitting element 120A and the second light emitting element 120B is collected by the lens member 260. The first light emitting element 120A is disposed such that the imaginary line OA1 meets the upper surface 440a at a location near the first light emitting element 120A. With this arrangement, the light that entered the lens member 260 is directed further towards the lens optical axis OB than the intersection between the imaginary line OA1 and the upper surface 440a. Similarly, the second light emitting element 120B is disposed such that the imaginary line OA2 meets the upper surface 440a at a location near the second light emitting element 120B. With this arrangement, the light that entered the lens member 260 is directed further towards the lens optical axis OB than the intersection between the imaginary line OA2 and the upper surface 440a. In this manner, the first light emitting element 120A and the second light emitting element 120B are disposed to allow light emitted from them to travel towards the center of the upper surface 440a of the wavelength conversion member 440.

The light that entered the upper surface 440a of the wavelength conversion member 440 and exited the upper surface 440a after undergoing wavelength conversion is collimated by the lens member 260 before exiting upwards from the lens emission surface 262. Constructing the device to allow the lens member 260 to collect the outgoing light from the first light emitting element 120A and the second light emitting element 120B to be incident on the wavelength conversion member 440 can reduce the spreading of the light when entering the wavelength conversion member 440. This, as a result, can miniaturize the wavelength conversion member 440. Furthermore, allowing light emitted from the wavelength conversion member 440 to enter the lens member 260 makes it possible to control the wavelength converted light that exits upwards by collimating or the like.

When viewed from above, the outline of the wavelength conversion member 440 is enclosed by the lens member 260. In the third direction Z, moreover, the lowermost point of the oblique surface 417a of the first protruded part 417A (or the oblique surface 417b of the second protruded part 417B) is positioned lower than the upper surface 440a of the wavelength conversion member 440. Employing such an oblique surface can bring the emission surface 120a of the first light emitting element 120A (or the emission surface 120b of the second light emitting element 120B) closer to the lens emission surface 262 of the lens member 260. In the example illustrated, when viewed from above, the shortest distance from the emission surface 120a (or 120b) to the outline of the lens member 260 is smaller than the shortest distance from the outline of the wavelength conversion member 440 to the outline of the lens member 260.

The flat portion of the lens incident surface 261 of the lens member 260 is partly in contact with the upper surface 418a of the third protruded part 418A and the upper surface 418b of the fourth protruded part 418B. The sum of the areas of overlap between the lens incident surface 261 of the lens member 260 and the upper surface 418a and between the lens incident surface 261 of the lens member 260 and the upper surface 418b is 40% or less of the total area of the lens member 260 when viewed from above. More preferably, the sum of the areas described above is 30% or less of the total area of the lens member 260 when viewed from above. When viewed from above, moreover, the sum of the areas described above is the same as or smaller than the area of the upper surface 440a of the wavelength conversion member 440, more preferably, 80% or less.

The light emitting device 400 according to the fourth embodiment has been explained thus far, but the lens member 160 of the first embodiment may be used in place of the lens member 260. In the case of using the lens member 160 of the first embodiment, the third protruded part 418A and the fourth protruded part 418B do not have to be provided. For example, the upper surface 440a of the wavelength conversion member 440 and the lens incident surface 161 of the lens member 160 may be bonded together by using an adhesive or the like.

The light emitting devices 100, 101, 200, 300, 301, and 400 can be utilized, for example, as automotive headlights. Otherwise, these light emitting devices can be utilized as light sources for lighting fixtures, projectors, head mounted displays, backlights for other displays, and the like.

Certain embodiments of the present invention have been explained in detail.

The present invention is not limited to those described above, and changes may be made to the details of the elements disclosed above, allowing for various modifications and replacements without deviating from the scope of the claims or the spirit of the invention.

What is claimed is:

1. A light emitting device comprising:
a base;
a light emitting element disposed on an upper surface of the base and configured to emit light;
a wavelength conversion member disposed on the upper surface of the base, the wavelength conversion member having
an incident surface on which the light is to be incident, and
a light emission surface through which the light is extracted out of the wavelength conversion member, the light emission surface being different from the incident surface;
a lens member bonded to the wavelength conversion member on a light emission surface side of the wavelength conversion member; and
a frame part connected to the base and forming a sealed space in which the light emitting element, the wavelength conversion member, and the lens member are sealed.

2. The light emitting device according to claim 1, wherein
the light emitting element is configured to emit the light laterally from a lateral side of the light emitting element,
the wavelength conversion member is disposed facing the lateral side of the light emitting element so that the light emitted from the light emitting element is incident on the light incident surface, and
a plane, in which the light emission surface lies, intersects with a plane in which the light incident surface lies.

3. The light emitting device according to claim 2, wherein
the wavelength conversion member has a phosphor part containing a phosphor and a surrounding part surrounding the phosphor part,
at least a portion of a lateral surface of the phosphor part is exposed from the surrounding part at the light incident surface, and
an upper surface of the phosphor part and an upper surface of the surrounding part are included in the light emission surface.

4. The light emitting device according to claim 3, wherein
the lens member has a lens incident surface and a lens emission surface, the lens emission surface having a curved shape at least in part, and
when viewed from above,
the lens incident surface of the lens member encloses an outline of the upper surface of the phosphor part of the wavelength conversion member, and
the lens incident surface of the lens member overlaps at least a portion of the upper surface of the surrounding part of the wavelength conversion member.

5. The light emitting device according to claim 4, wherein
when viewed from above, the outline of the surrounding part of the wavelength conversion member encloses an outline of the lens incident surface of the lens member.

6. The light emitting device according to claim 4, wherein
the lens member has a lens part and a flat part,
when viewed from above, an overlapping area between the lens part of the lens member and the upper surface of the phosphor part of the wavelength conversion member is larger than an overlapping area between the lens part of the lens member and the upper surface of the surrounding part of the wavelength conversion member.

7. The light emitting device according to claim 6, wherein
when viewed from above, an overlapping area between the lens member and the upper surface of the phosphor part of the wavelength conversion member is smaller than an overlapping area between the lens member and the upper surface of the surrounding part of the wavelength conversion member.

8. The light emitting device according to claim 6, wherein
when viewed from above, an area in which the lens part of the lens member overlaps the upper surface of the phosphor part of the wavelength conversion member without overlapping a lower surface of the phosphor part is 5% or greater of an area in which the lens part of the lens member overlaps both the upper surface and the lower surface of the phosphor part.

9. The light emitting device according to claim 8, wherein
a line coinciding with a lens optical axis of the lens member passes through the upper surface and the lower surface of the phosphor part of the wavelength conversion member.

10. The light emitting device according to claim 4, wherein
the lens incident surface of the lens member and the light emission surface of the wavelength conversion member are bonded via a light transmissive bonding member, and
the light transmissive bonding member is applied across the upper surface of the phosphor part of the wavelength conversion member and the upper surface of the surrounding part of the wavelength conversion member when viewed from above.

11. The light emitting device according to claim 4, wherein
the lens incident surface of the lens member and the light emission surface of the wavelength conversion member are bonded via a light transmissive bonding member, and
the light transmissive bonding member is applied on the upper surface of the surrounding part of the wavelength conversion member and is not applied on the upper surface of the phosphor part of the wavelength conversion member.

12. The light emitting device according to claim 11, wherein
the lens incident surface of the lens member has a curved shape, and
the lens member is bonded to the upper surface of the surrounding part of the wavelength conversion member and not bonded to the upper surface of the phosphor part of the wavelength conversion member.

13. The light emitting device according to claim 1, wherein
the frame part includes
a lateral part surrounding the base, and
a cover disposed above the lateral part, and
a length of the lens member is smaller than one half of a length of the sealed space in an optical axis direction of the light.

14. The light emitting device according to claim 13, wherein
the length of the lens member is larger than a length of a lower surface of the wavelength conversion member in the optical axis direction of the light.

15. The light emitting device according to claim 13, further comprising
a second lens member disposed above the cover, wherein
the second lens member having a length that is equal to or greater than twice the length of the lens member in the optical axis direction of the light.

16. The light emitting device according to claim 15, wherein
the second lens member is bonded to the upper surface of the cover.

17. The light emitting device according to claim 15, wherein
the second lens member is integrally formed with the cover.

18. A light emitting device comprising:
a base;
a first light emitting element and a second light emitting element disposed on an upper surface of the base and configured to emit light;
a wavelength conversion member disposed on the upper surface of the base between the first light emitting element and the second light emitting element when viewed from above, the wavelength conversion member having
an incident surface on which the light is to be incident, and
a light emission surface through which the light is extracted out of the wavelength conversion member;
a lens member disposed above the wavelength conversion member on a light emission surface side of the wavelength conversion member; and
a frame part connected to the base and forming a sealed space in which the light emitting element, the wavelength conversion member, and the lens member are sealed.
